(19) United States
(12) Patent Application Publication
(10) Pub. No.: US 2025/0293722 A1
(43) Pub. Date: Sep. 18, 2025

(54) HIGH SPEED RECEIVER FOR MULTI-GIGA HERTZ OPERATIONS

(71) Applicant: Micron Technology, Inc., Boise, ID (US)

(72) Inventor: Vivek Venkata Kalluru, San Jose, CA (US)

(73) Assignee: Micron Technology, Inc., Boise, ID (US)

(21) Appl. No.: 19/060,556

(22) Filed: Feb. 21, 2025

Related U.S. Application Data
(60) Provisional application No. 63/564,958, filed on Mar. 13, 2024.

(51) Int. Cl. H04B 1/18; H03F 1/22; H04B 1/16; H04L 25/08

(52) U.S. Cl. CPC H04B 1/18; H03F 1/22; H04B 1/1607; H04L 25/085

(57) ABSTRACT

Methods, systems, and devices for techniques of an input receiver of an input/output (I/O) circuit operable to communicate data are provided. An input receiver includes an analog frontend configured to receive analog differential input signals from external of the I/O circuit. The analog frontend comprises a cascode circuit having differential inputs configured to receive the analog differential input signals and provide frontend differential output signals based on the received analog differential input signals, the cascode circuit being operable in a multi-giga Hertz frequency range. The input receiver further includes a biasing circuit configured to control biasing voltages of the cascode circuit; and cascaded inverter-based stages electrically coupled to the analog frontend to receive the frontend differential output signals and output equalized differential signals representing the received data.

### CROSS-REFERENCE TO RELATED APPLICATION

This application claims priority to U.S. Provisional Application No. 63/564,958, filed on Mar. 13, 2024, entitled “HIGH SPEED RECEIVER FOR MULTI-GIGA HERTZ OPERATIONS,” the content of which is incorporated by reference in its entirety for all purposes.

### TECHNICAL FIELD

This disclosure relates to one or more systems and circuits for memory, including input/output (I/O) circuit techniques for an input receiver used in high speed data communication operations.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIGS. 1A and 1B illustrate an example of a host system and a memory system that support techniques for high-speed data operations, in accordance with examples as disclosed herein.

FIG. 1C is a block diagram of a memory device in communication with a memory system controller of a memory system, in accordance with examples as disclosed herein.

FIGS. 2A-2C are illustrative schematics of portions of an array of memory cells in a memory device, in accordance with examples as disclosed herein.

FIG. 2D illustrates an example of a memory device including multiple blocks of memory cells in accordance with examples as disclosed herein.

FIG. 3 is a block diagram of an example apparatus for implementing one or more systems and for performing one or more methods described herein, in accordance with examples as disclosed herein.

FIG. 4 is a block diagram of an example memory device with an input receiver, in accordance with examples as disclosed herein.

FIG. 5A are circuit diagrams illustrating a common source circuit and a cascode circuit, in accordance with examples as disclosed herein.

FIG. 5B is a circuit diagram of an analog frontend with a folded cascode circuit, in accordance with examples as disclosed herein.

FIG. 6 illustrates a circuit diagram of a biasing circuit configured to control biasing voltages of an analog frontend circuit, in accordance with examples as disclosed herein.

FIG. 7A is a block diagram of an inverter-based stage and the associated gain profiles, in accordance with examples as disclosed herein.

FIG. 7B is a block diagram of an inverter-based stage with a pair of cross-coupled inverters, in accordance with examples as disclosed herein.

FIG. 7C illustrates gain profiles of the inverter-based stage with a pair of cross-coupled inverters, in accordance with examples as disclosed herein.

FIG. 8A is a block diagram of cascaded inverter-based stages with pairs of cross-coupled inverters, in accordance with examples as disclosed herein.

FIG. 8B illustrates gain profiles of the cascaded inverter-based stages with pairs of cross-coupled inverters, in accordance with examples as disclosed herein.

FIG. 8C are illustrative signal waveforms for an analog frontend with and without cascode circuits, in accordance with examples as disclosed herein.

### DETAILED DESCRIPTION

A memory device frequently includes input/output (I/O) circuits for receiving and/or transmitting data at a high speed such as in the multiple Giga Hertz frequency range. For example, data may be communicated between the memory device and a host system at 3.6 gigatransfers per second (GTs) or more. Transferring data at such a high speed imposes a higher requirement on the input receiver of the memory device. An input receiver receives high-speed analog differential signals representing data. The input receiver includes an analog frontend for receiving such high-speed analog differential signals. The input receiver may amplify the received analog differential signals, amplify the signals, filter them, and/or perform other processing of the signals. The input receiver then provides output differential signals or a single-ended signal for downstream processing such as digitizing, clock recovering, etc.

Existing input receivers may be bandwidth limited due to the high gate resistance caused by the Miller effect and its poles. A pole frequency is a frequency at which the transfer function of a system approaches infinity. The location of poles of the input receiver determines how quickly the input receiver can respond to input signals and whether it remains stable. Operating at a high speed, existing input receivers may not respond quickly to the input signals and may become unstable. Further, when the power supply of the input receiver varies, which sometimes is inevitable, the frontend output signals' common mode movement and the trip point movements may not be equal to each other, resulting in duty cycle distortion.

Techniques and circuits described herein provide an input receiver using a cascode circuit to receive high-speed differential input signals. The cascode circuit can be configured to reduce the Miller effect of the existing input receivers, and thereby reducing the gate resistance effect and increasing the bandwidth of the input receiver. The cascode circuit used in the analog frontend further achieves continuous time linear equalization (CTLE) to provide equalized differential output signals representing the data. The differential output signals can thus have better eye openings, thereby improving the signal quality and integrity at the multi-giga Hertz transfer operation range. The cascode circuit can enable the input receiver to have a higher bandwidth and higher transfer speed without, or without substantially, increasing the layout area and power of the input receiver.

Techniques and circuits described herein further provide an input receiver using cascaded inverter-based stages. An inverter-based stage (also referred to as an active inductor stage) can be coupled to receive the differential output signals from the analog frontend. The inverter-based stage can further amplify the frontend differential output signals. Cascaded inverter-based stages include multiple inverter-based stage cascaded in series. Cascaded inverter-based stages can provide a higher amplification gain than a single inverter-based stage. By using the cascaded inverter-based stages, the zero frequency and the pole frequency of the input receiver can be extended without, or without significantly, increasing the power consumption. A pole frequency, as described above, is a frequency at which the transfer function of a system approaches infinity. And a zero frequency is the frequency at which the transfer function of a system approaches zero. Thus, extending the zero frequency and/or the pole frequency of the input receiver effectively extends the passband of the input receiver, thereby increasing the bandwidth. The techniques and circuits are further described in greater detail below.

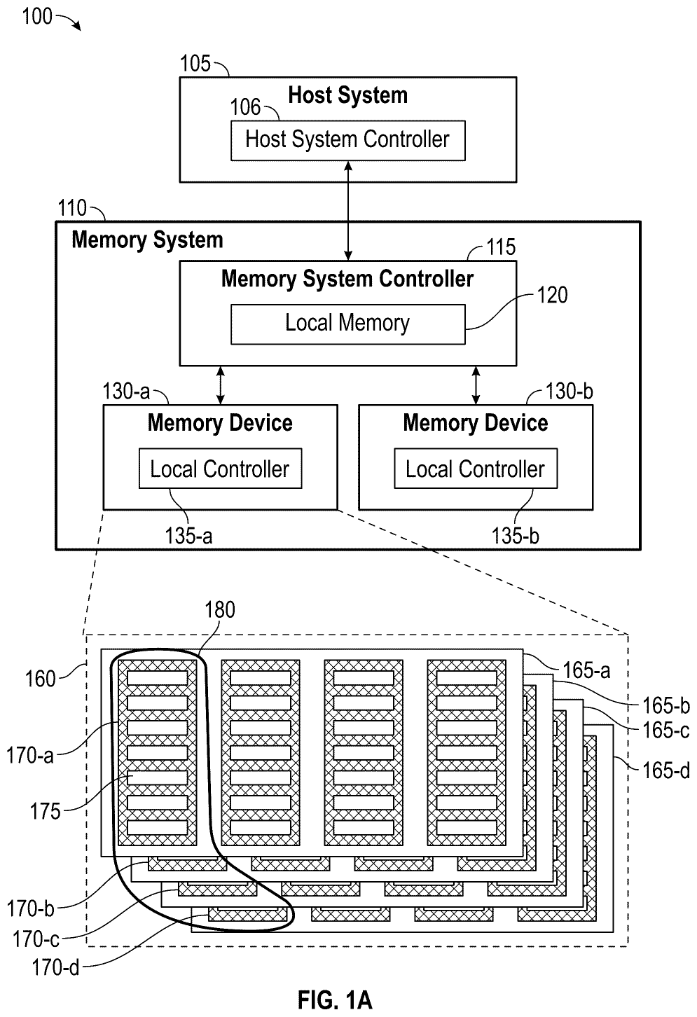

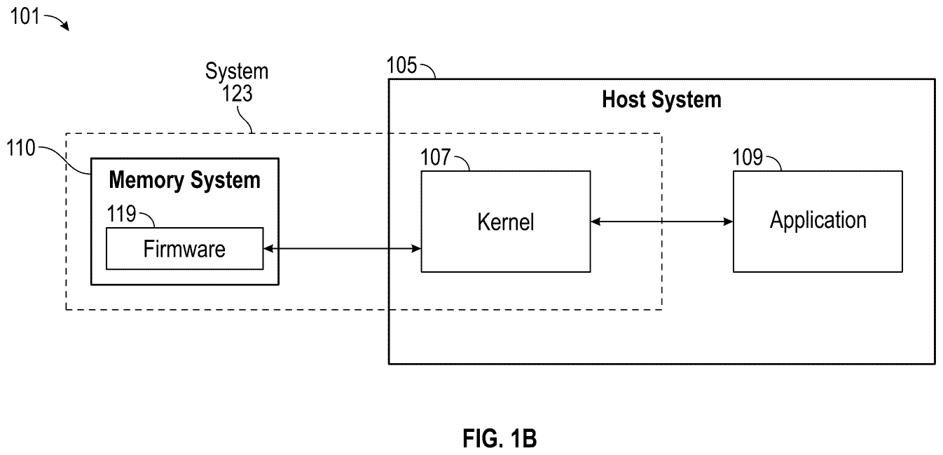

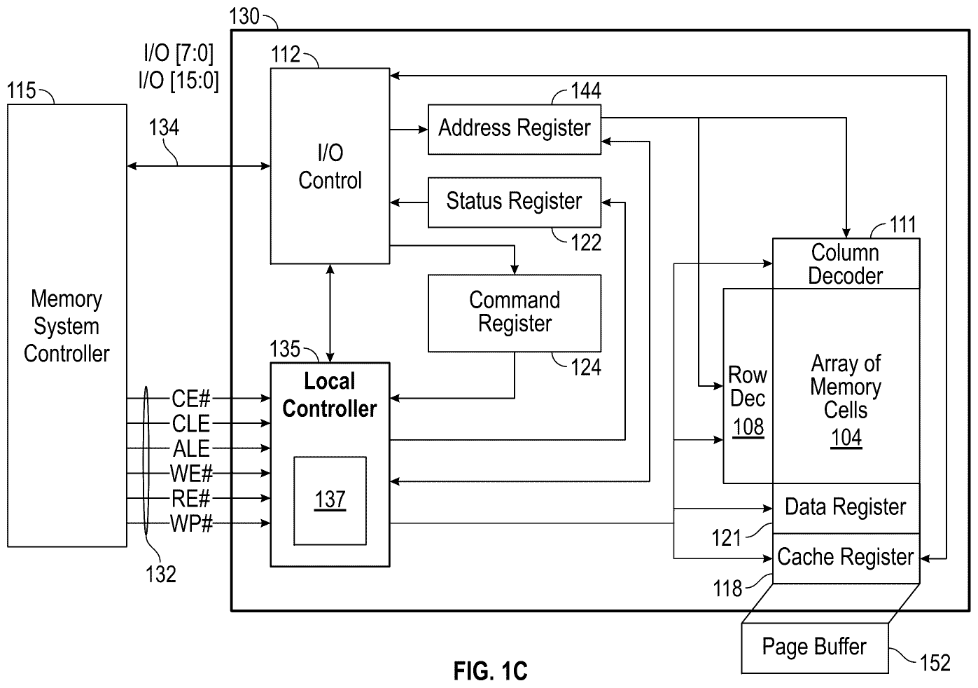

FIG. 1A illustrates an example of a system 100 that supports techniques for high speed data operations in accordance with examples as disclosed herein. System 100 includes a host system 105 coupled with a memory system 110. System 100 may be included in a computing device such as a desktop computer, a laptop computer, a network server, a mobile device, a vehicle (e.g., airplane, drone, train, automobile, or other conveyance), an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

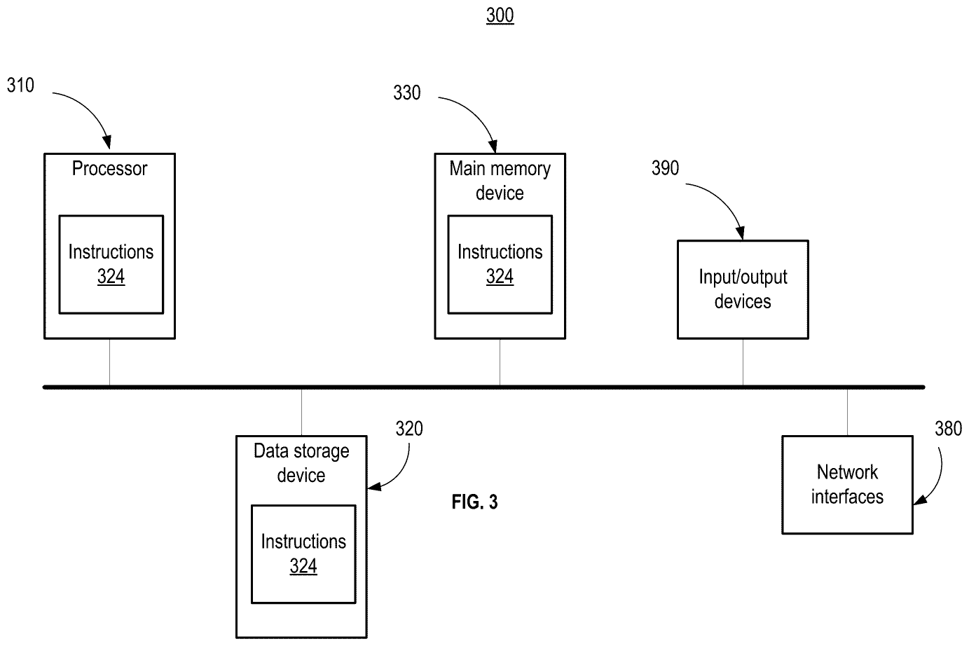

System 100 may include a host system 105, which may be coupled with memory system 110. In some examples, this coupling may include an interface with a host system controller 106, which may be an example of a controller or control component configured to cause host system 105 to perform various operations in accordance with examples as described herein. Host system 105 may include one or more devices and, in some cases, may include a processor chipset and a software stack executed by the processor chipset. Host system 105 may be implemented by, for example, an apparatus 300 shown in FIG. 3. For example, host system 105 may include an application configured for communicating with memory system 110 or a device therein. The processor chipset may include one or more cores, one or more caches (e.g., memory local to or included in host system 105), a memory controller (e.g., NVDIMM controller), and a storage protocol controller (e.g., peripheral component interconnect express (PCIe) controller, serial advanced technology attachment (SATA) controller). Host system 105 may use memory system 110, for example, to write data to memory system 110 and read data from memory system 110. Although one memory system 110 is shown in FIG. 1A, the host system 105 may be coupled with any quantity of memory systems 110.

Host system 105 may be coupled with memory system 110 via at least one physical host interface. Host system 105 and memory system 110 may, in some cases, be configured to communicate via a physical host interface using an associated protocol (e.g., to exchange or otherwise communicate control, address, data, and other signals between memory system 110 and host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a Graphical Double Data Rate (GDDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of host system 105 and a memory system controller 115 of memory system 110. In some examples, host system 105 may be coupled with memory system 110 (e.g., host system controller 106 may be coupled with memory system controller 115) via a respective physical host interface for each memory device 130 included in the memory system 110, or via a respective physical host interface for each type of memory device 130 included in memory system 110.

Memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1A, memory system 110 may include any quantity of memory devices 130. Further, if the memory system 110 includes more than one memory device 130, different memory devices 130 within the memory system 110 may include the same or different types of memory cells.

Memory system controller 115 may be coupled with and communicate with host system 105 (e.g., via the physical host interface) and may be an example of a controller or control component configured to cause memory system 110 to perform various operations in accordance with examples as described herein. Memory system controller 115 may also be coupled with and communicate with memory devices 130 to perform operations such as reading data, writing data, erasing data, or refreshing data at a memory device 130—among other such operations—which may generically be referred to as access operations. In some cases, memory system controller 115 may receive commands from the host system 105 and communicate with one or more memory devices 130 to execute such commands (e.g., at memory arrays within the one or more memory devices 130). For example, memory system controller 115 may receive commands or operations from host system 105 and may convert the commands or operations into instructions or appropriate commands to achieve the desired access of memory devices 130. In some cases, memory system controller 115 may exchange data with host system 105 and with one or more memory devices 130 (e.g., in response to or otherwise in association with commands from host system 105). For example, memory system controller 115 may convert responses (e.g., data packets or other signals) associated with the memory devices 130 into corresponding signals for host system 105.

Memory system controller 115 may be configured for other operations associated with memory devices 130. For example, memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from host system 105 and physical addresses (e.g., physical block addresses) associated with memory cells within memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to memory system controller 115. Memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

Memory system controller 115 may also include a local memory 120. In some cases, local memory 120 may include read-only memory (ROM) or other memory that may store operating code (e.g., executable instructions) executable by memory system controller 115 to perform functions ascribed herein to memory system controller 115. In some cases, local memory 120 may additionally, or alternatively, include static random access memory (SRAM) or other memory that may be used by memory system controller 115 for internal storage or calculations, for example, related to the functions ascribed herein to memory system controller 115.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on a same semiconductor die or within a same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1A, a memory device 130-a may include a local controller 135-a and a memory device 130-b may include a local controller 135-b. In the examples illustrated in this disclosure (e.g., the example shown in FIG. 1C), local controller 135 is disposed on the same semiconductor die as the memory array (e.g., array 104); and a separate memory system controller 115 is disposed on a different die. In other examples, some portions of memory device 130 may be disposed on a first die and other portions of memory device 130 may be disposed on a second die different from the first die. For instance, the first die may include the array of memory cells 104 and its associated circuitry such as the column decoder 111 and row decoder 108, etc. The second die may include logic circuitry, power circuitry, or other circuitry of device 130. Thus, the second die may include system controller 115, I/O control 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, a memory system controller 115 and a local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

In some cases, a memory device 130 may be or include a NAND device (e.g., NAND flash device). A memory device 130 may be or include a semiconductor die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of memory blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of memory blocks 170 and, in some cases, concurrent operations may be performed on different planes 165. For example, concurrent operations may be performed on memory cells within different blocks 170 so long as the different blocks 170 are in different planes 165. In some cases, an individual memory block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in a same page 175 may share (e.g., be coupled with) a common word line, and memory cells in a same string may share (e.g., be coupled with) a common digit line (which may alternatively be referred to as a bit line). Example memory cells structures are shown in more detail below using illustrative schematics.

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a memory block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, L2P (logical-to-physical) mapping tables may be maintained and data may be marked as valid or invalid at the page level of granularity, and a page 175 may contain valid data, invalid data, or no data. Invalid data may be data that is outdated, which may be due to a more recent or updated version of the data being stored in a different page 175 of the memory device 130. Invalid data may have been previously programmed to the invalid page 175 but may no longer be associated with a valid logical address, such as a logical address referenced by the host system 105. Valid data may be the most recent version of such data being stored on the memory device 130. A page 175 that includes no data may be a page 175 that has never been written to or that has been erased.

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

System 100 may include any quantity of non-transitory computer readable media that support techniques for logical-to-physical table compression. For example, host system 105 (e.g., a host system controller 106), memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to host system 105, memory system 110, or a memory device 130. For example, such instructions, if executed by host system 105 (e.g., by a host system controller 106), by memory system 110 (e.g., by a memory system controller 115), or by a memory device 130 (e.g., by a local controller 135), may cause host system 105, memory system 110, or memory device 130 to perform associated functions as described herein.

In some cases, a memory system 110 may compress an L2P mapping to expand the quantity of physical addresses mapped by the L2P mapping. For example, if a set of consecutive entries of an uncompressed L2P mapping includes consecutive physical addresses, memory system 110 may compress the consecutive entries into a single entry which includes a starting physical address of the consecutive physical addresses. Additionally, memory system 110 may include an indication of a starting logical address corresponding to the starting physical address in the compressed entry. To identify a physical address within the compressed entry, memory system 110 may determine an offset between a logical address corresponding to the physical address (e.g., a logical address included in a read command for data stored at the physical address) and the starting physical address using the indication, and may apply the offset to the starting physical address to determine the physical address. Compressing the L2P mapping may allow the L2P mapping to cover an expanded range of physical address space without increasing the size of the L2P mapping.

FIG. 1B illustrates an example of a system diagram 101 that illustrates communication between host system 105 and memory system 110 via using a kernel and firmware, in accordance with examples as disclosed herein. System diagram 101 may include a memory system 110, a kernel 107, and an application 109. The memory system 110 may include a firmware 119. Firmware 119 may be implemented by a controller and/or other circuitry of the memory system (e.g., memory system controller 115 and/or local controllers 135 shown in FIG. 1A). In some examples, a system 123 as described herein may include memory system 110 and kernel 107. Additionally, a host system 105 may include kernel 107 and the application 109.

As described above, memory system 110 may include multiple memory devices, including non-volatile memory devices and volatile memory devices (e.g., local memory 120), configured to store and retrieve data. Firmware 119 may refer to software stored within a memory array within memory system 110 (e.g., a non-volatile memory device within the memory system 110) and/or a local memory 120 as shown in FIG. 1A. Firmware 119 may provide low-level control functions for the memory system 110. For example, firmware 119 may function as an interface between memory system 110 and other components of system 123, and host system 105 may issue access operations to memory system 110 by interfacing with firmware 119. In some examples, firmware 119 may be or be included within or implemented by a memory system controller 115, as described herein with reference to FIG. 1A. In some examples, memory system 110 may store a logical-to-physical (L2P) mapping that maps logical addresses to physical addresses within a non-volatile memory device (e.g., in a logical-to-physical table). To perform a memory access operation, memory system 110 may move a portion of the logical-to-physical mapping corresponding to one or more logical addresses (e.g., indicated by kernel 107) from the non-volatile memory device to a volatile memory device.

Kernel 107 may function as an interface between host system 105 and components associated with host system 105, such as an operating system of host system 105. Additionally, kernel 107 may perform resource allocation and file management, among other operations, for host system 105. For example, an application 109 running within host system 105 may access information stored within memory system 110 by issuing commands to kernel 107, which may indicate files to be accessed. Kernel 107 may store mapping information associated with the files. For example, a file may be associated with a file name, and may correspond to a range of logical block addresses. Kernel 107 may store mapping information (e.g., a mapping table) that may track logical block addresses corresponding to files of host system 105. In some examples, application 109 may issue an access command to kernel 107 indicating a file name, and offset, and a length associated with a file to be accessed, and kernel 107 may retrieve a one or more logical block addresses corresponding to the file to be accessed. Kernel 107 may then communicate with firmware 119 to indicate the one or more logical block addresses to memory system 110, and memory system 110 may perform an access operation based on the one or more logical block addresses. Memory system 110 may communicate the accessed information to kernel 107 (e.g., via the firmware 119).

In some examples, kernel 107 may communicate with firmware 119 using information units (e.g., UFS protocol information units (UPIUs)). For example, kernel 107 may issue or receive commands, responses, data, or other information via information units exchanged with the firmware 119. An information unit may refer to a data packet that may contain a header segment and one or more transaction specific fields. In some examples, an information unit may additionally include one or more extended header segments, one or more data segments, or a combination thereof. The header segments of an information unit may indicate information associated with a destination for the information unit, a source of the information unit, a function request, whether additional data or parameters are to be transmitted, whether the additional data or parameters are included within the information unit or to be sent in a following information unit, or any combination thereof. The transaction specific fields may be used for additional fields depending on the operation associated with the information unit. The data segments may be used to include data to be transferred from a device to another.

In some examples, a command information unit (e.g., a command UPIU) may be an example of an information unit associated with the transmission of a command (e.g., an SCSI command) and may indicate a device to perform some operation indicated by the command information unit. For example, the command information unit may include a block descriptor (e.g., a command descriptor block) which may indicate information related to the operation indicated by the command information unit. In some examples, kernel 107 may transfer a command information unit to memory system 110 to indicate memory system 110 of an operation to be performed by memory system 110.

In some examples, to perform an access operation, memory system 110 may load a L2P mapping associated with information to be accessed. For example, memory system 110 may transfer a portion of a logical-to-physical mapping associated with the information to be accessed from a non-volatile memory device of memory system 110 (e.g., NAND memory) to a volatile memory device (e.g., an SRAM) of the memory system 110. In another example, host system 105 may notify memory system 110 of a logical block address range corresponding to an upcoming access operation (e.g., prior to issuing an access command). Memory system 110 may use the logical block address range to load (e.g., pre-load, pre-fetch) an associated portion of a L2P mapping (e.g., from a non-volatile memory device to a volatile memory device) prior to receiving an access command that indicates memory system 110 to perform the access operation. Accordingly, after host system 105 issues the access command, memory system 110 may issue a response to host system 105 faster as memory system 110 has already loaded relevant portions of the L2P mapping associated with the access operation.

The above description of the system diagram 101 are illustrative examples of communication between host system 105 and memory system 110 by using a kernel 107, application 109, and firmware 119. It is understood that additional ways of communication, including function calls, commands, responses, messages, etc. can be implemented using host system 105 and memory system 110, and/or additional systems or components.

FIG. 1C is a simplified block diagram of a memory device 130 in communication with a memory system controller 115 of a memory system (e.g., memory system 110 of FIGS. 1A and 1B), according to an embodiment. As shown in FIG. 1C and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1C) of at least a portion of the array of memory cells 104 are capable of being programmed to one of at least two target data states for storing any number of bits of information.

With continued reference to FIG. 1C, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 114 is in communication with I/O control circuitry 112 and row decode circuitry 108 and column decode circuitry 111 to latch the address signals prior to decoding. Row decode circuitry 108 and column decode circuitry 111 may simply be referred to as row decoder 108 and column decoder 111, respectively. A command register 124 is in communication with the I/O control circuitry 112 and local controller 135 to latch incoming commands.

A memory controller (e.g., the local controller 135 internal to memory device 130) controls access to the array of memory cells 104 in response to the commands and generates status information for the external memory system controller 115, i.e., local controller 135 is configured to perform access operations (e.g., read operations, programming operations, and/or erase operations) on the array of memory cells 104. The local controller 135 is in communication with row decode circuitry 108 and column decode circuitry 111 to control the row decode circuitry 108 and column decode circuitry 111 according to the addresses.

Local controller 135 is also in communication with a cache register 118 and a data register 121. In some embodiments, one or more cache registers 118 can collectively form at least a part of a cache buffer. Cache register 118 latches or buffers data, either incoming or outgoing, as directed by local controller 135 to temporarily store data while the array of memory cells 104 is busy writing or reading, respectively, other data. During a program operation (e.g., write operation), data can be passed from cache register 118 to data register 121 for transfer to the array of memory cells 104; then new data can be latched in cache register 118 from I/O control circuitry 112. During a read operation, data can be passed from cache register 118 to the I/O control circuitry 112 for output to memory system controller 115; then new data can be passed from data register 121 to cache register 118. In some embodiments, cache register 118 and/or data register 121 can form at least a portion of a page buffer 152 of memory device 130. Page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and local memory controller 135 to latch the status information for output to memory system controller 115.

As shown in FIG. 1C, memory device 130 receives various control signals via local controller 135 from memory system controller 115 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over control link 132 depending upon the nature of memory device 130. In one embodiment, memory device 130 receives command signals (which represent commands), address signals (which represent addresses), and data signals (which represent data) from the memory system controller 115 over a multiplexed input/output (I/O) bus 134 and outputs data to the memory system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 114. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the memory system controller 115), such as conductive pads or conductive bumps as are commonly used. While the above description using 16 bits I/O bus 134 as an example, it is understood that bus 134 can be configured to any number of bits (e.g., 64 bits).

It will be appreciated by those skilled in the art that additional circuitry and signals can be provided, and that memory device 130 of FIG. 1C has been simplified. It should be recognized that the functionality of the various block components described with reference to FIG. 1C may not necessarily be segregated to distinct components or component portions of an integrated circuit device. For example, a single component or component portion of an integrated circuit device could be adapted to perform the functionality of more than one block component of FIG. 1C. Alternatively, one or more components or component portions of an integrated circuit device could be combined to perform the functionality of a single block component of FIG. 1C. Additionally, while specific I/O pins are described in accordance with popular conventions for receipt and output of the various signals, it is noted that other combinations or numbers of I/O pins (or other I/O node structures) can be used in the various embodiments.

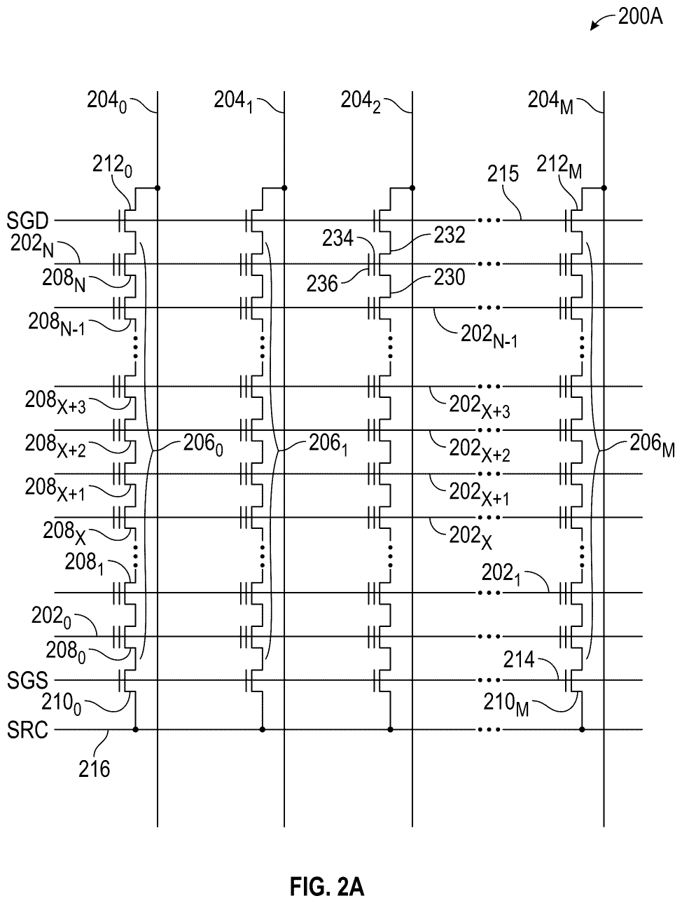

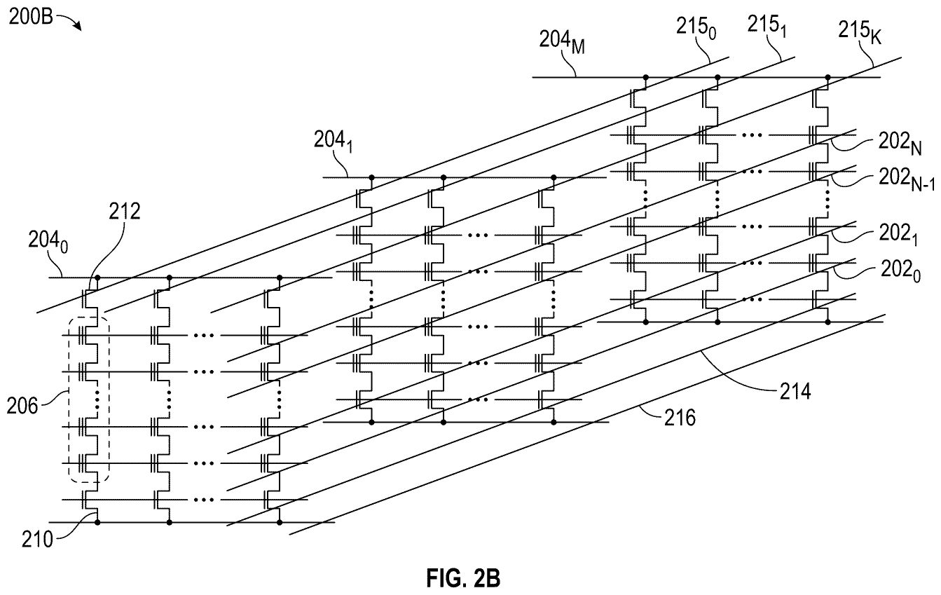

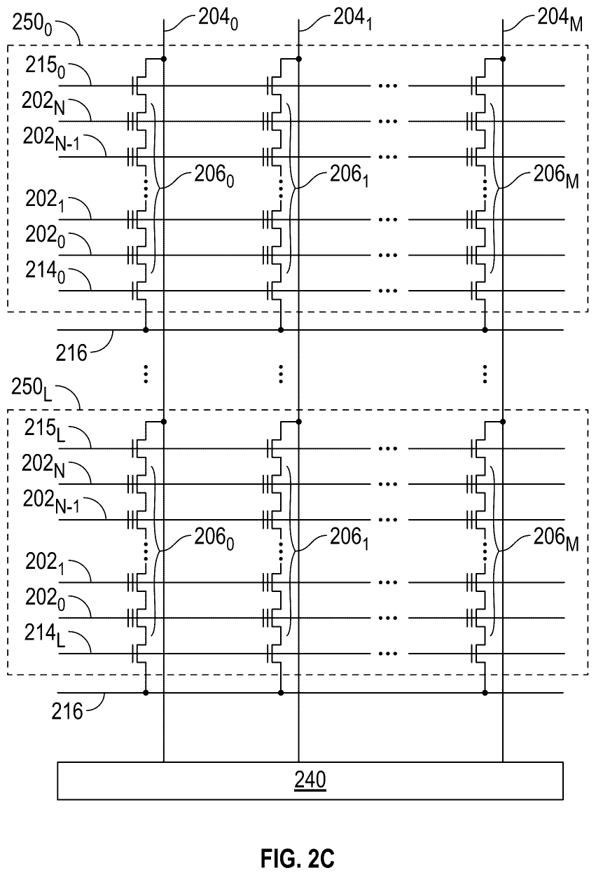

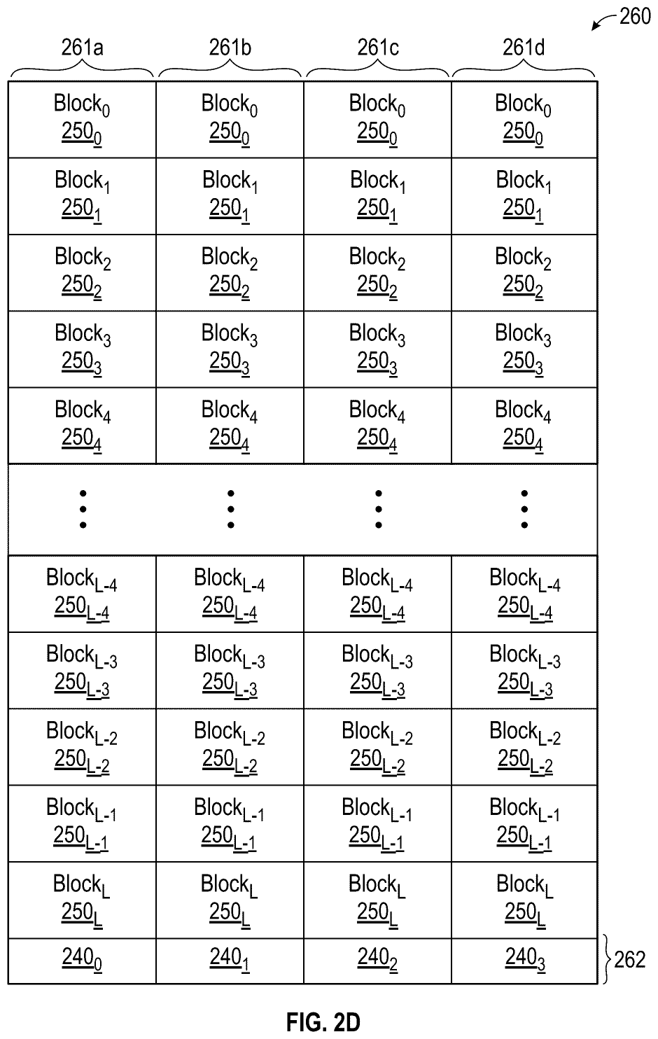

FIG. 2A-2B are example schematics of portions of an array of memory cells 200A, such as a NAND memory array. Array of memory cells 200A may be an example of memory array 104 of a memory device 130 as described with reference to FIG. 1C according to an embodiment. Memory array 200A includes access lines, such as word lines 202₀ to 202_{N}, and data lines, such as bit lines 204₀ to 204_{M}. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 2060 to 206M. Each NAND string 206 can be connected (e.g., selectively connected) to a common source (SRC) 216 and can include memory cells 208₀ to 208_{N}. Memory cells 208 can represent non-volatile memory cells for storage of data. Memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, select gates 210 and 212 can utilize a structure similar to (e.g., the same as) memory cells 208. Select gates 210 and 212 can represent a number of select gates connected in series, with each select gate in series configured to receive a same or independent control signal.

A source of each select gate 210 can be connected to common source 216. The drain of each select gate 210 can be connected to a memory cell 208₀ of the corresponding NAND string 206. For example, the drain of select gate 210₀ can be connected to memory cell 208₀ of the corresponding NAND string 2060. Therefore, each select gate 210 can be configured to selectively connect a corresponding NAND string 206 to the common source 216. A control gate of each select gate 210 can be connected to select line 214.

The drain of each select gate 212 can be connected to bit line 204 for the corresponding NAND string 206. For example, the drain of select gate 212₀ can be connected to the bit line 204₀ for the corresponding NAND string 2060. The source of each select gate 212 can be connected to a memory cell 208_{N} of the corresponding NAND string 206. For example, the source of select gate 212₀ can be connected to memory cell 208_{N} of the corresponding NAND string 2060. Therefore, each select gate 212 can be configured to selectively connect a corresponding NAND string 206 to the corresponding bit line 204. A control gate of each select gate 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. Memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2A, it is apparent from the figure that the bit lines 204 of the array of memory cells 200A can be numbered consecutively from bit line 204₀ to bit line 204_{M}. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory device described with reference to FIG. 1B, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. In some embodiments, each sub-block or string of memory cells has a separate select line 214 from other sub-blocks or strings. In some embodiments, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a higher storage capacity. Furthermore, in a memory device having three-dimensional NAND memory arrays, transistors in memory cells are spaced out, and therefore interference and electron leaks can be reduced.

As described above, memory cells can be grouped into memory blocks. FIG. 2C depicts groupings of NAND strings 206 into blocks of memory cells 250, e.g., blocks of memory cells 250₀-250_{L}. Blocks of memory cells 250 can be groupings of memory cells 208 that can be erased together in a single erase operation. The group of memory cells that can be erased together is also referred to as an erase block. Each block of memory cells 250 can represent those NAND strings 206 commonly associated with a single select line 215, e.g., select line 215₀. The common source 216 for the block of memory cells 250₀ can be a same source as the source 216 for the block of memory cells 250_{L}. For example, each block of memory cells 250₀-250_{L} can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 250₀-250_{L}.

The bit lines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bit lines 204.

FIG. 2D is a block schematic of a portion of an example array of memory cells 260. Array of memory cells 260 can be used as array 104 in a memory device 130 described with reference to FIG. 1C. The array of memory cells 260 is depicted as having four memory planes 261 (e.g., memory planes 261a-261d). Each of the memory planes 261 can correspond to planes 165 depicted in FIG. 1A. Each memory plane 261 can be in communication with a respective buffer portion 240, which can collectively form a page buffer 262. Page buffer 262 may be used to implement page buffer 152 shown in FIG. 1C. While four memory planes 261 are depicted, other numbers of memory planes 261 can be commonly in communication with a page buffer 262. Each memory plane 261 is depicted to include L+1 blocks of memory cells 250 (e.g., blocks of memory cells 250₀-250_{L}).

With continued reference to FIGS. 1C and 2A-2C, during a true erase operation (during which memory cells are actually being erased), local controller 135 (e.g., using an erase operation manager 137) can cause a common source voltage line, e.g., the SRC 216 (FIG. 2A), to be ramped to an erase voltage (Vera) with an erase pulse while the select gates 210₀ to 210_{M} (SGS transistors) are turned on. Ramping to this high bias erase voltage, and the subsequent recovery from this voltage ramping, may take a significant amount of time. Concurrently, the erase operation manager 137 can cause the select gates 212₀ to 212ₘ (FIG. 2A) to be turned off to enable the drains of the select gates 212₀ to 212ₘ to float, which causes the bit lines 204₀ to 204_{M} to also float. Further, the erase operation manager 137 can couple the word lines 202 (FIG. 2A) to ground, e.g., zero volts, or retain the word lines 202 at a low voltage. This set of voltage levels at the memory array 200A can create an erase potential that causes the memory cells 208₀ to 208_{N} to be erased, e.g., forces electrons to exit through a body of each memory cell and out the floating bit lines 204₀ to 204_{M}. In other embodiments, the reverse can be done so the select gates 210₀ to 210_{M} are turned off, causing the SRC line 216 to float while the voltage of the bit lines are ramped to Vera while the select gates 212₀ to 212_{M} are turned on. As mentioned earlier, in 3D NAND, one of the channel region, pillar, or bit line can also be ramped up in voltage to cause erasure of attached memory cells. Thus, for simplicity herein, reference to “memory line” should be understood to make reference to any of the SRC line or bit lines in 2D NAND or to any of channel, pillar, or bit lines in 3D NAND. In some embodiments, one or more sub-blocks, to include a physical block, of memory cells are erased during the same true erase operation. A block of memory cells can be generally understood to include four or more sub-blocks, wherein each sub-block includes a separate string of memory cells.

A high-level block diagram of an example apparatus 300 that may be used to implement systems, apparatus, and methods described herein is illustrated in FIG. 3. It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of at least some of the FIGS. 1-8C, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

As shown in FIG. 3, apparatus 300 may be used to implement a host system (e.g., host system 105 shown in FIG. 1A) that includes, is coupled to, or utilizes a memory system (e.g., memory system 110 of FIG. 1A). Apparatus 300 can be used to perform operations of a controller (e.g., to execute an operating system to perform operations corresponding to host system controller 106 and/or local controller 135 of FIG. 1A).

In some embodiments, apparatus 300 comprises a processor 310 operatively coupled to a data storage device 320 and a main memory device 330. Processor 310 controls the overall operation of apparatus 300 by executing computer program instructions 324 that define such operations. The instructions 324 include instructions to implement functionality of a controller (e.g., host system controller 106 and/or local controller 135 of FIG. 1A). The computer program instructions 324 may be stored in data storage device 320, or other computer-readable medium, and loaded into main memory device 330 when execution of the computer program instructions is desired. For example, processor 310 may be used to implement one or more components and systems described herein, such as host system controller 106 and/or local controller 135 (shown in FIG. 1A). Thus, the method steps of at least some of FIGS. 1-8C can be defined by the computer program instructions 324 stored in main memory device 330 and/or data storage device 320 and controlled by processor 310 executing the computer program instructions 324. For example, the computer program instructions 324 can be implemented as computer executable code programmed by one skilled in the art to perform an algorithm defined by the method steps discussed herein in connection with at least some of FIGS. 1-8C. Accordingly, by executing the computer program instructions, processor 310 executes an algorithm defined by the method steps of these aforementioned figures to perform operations (e.g., read, program, erase, etc.). Apparatus 300 also includes one or more network interfaces 380 for communicating with other devices via a network. Apparatus 300 may also include one or more input/output devices 390 that enable user interaction with apparatus 300 (e.g., display, keyboard, mouse, speakers, buttons, etc.).

Processor 310 may include both general and special purpose microprocessors and may be the sole processor or one of multiple processors of apparatus 300. Processor 310 may comprise one or more central processing units (CPUs), and one or more graphics processing units (GPUs), which, for example, may work separately from and/or multi-task with one or more CPUs to accelerate processing, e.g., for various image processing applications described herein. Processor 310, data storage device 320, and/or main memory device 330 may include, be supplemented by, or incorporated in, one or more application-specific integrated circuits (ASICs) and/or one or more field programmable gate arrays (FPGAs).

Data storage device 320 and main memory device 330 each comprise a tangible non-transitory computer readable storage medium. Data storage device 320, and main memory device 330, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices (NAND memory devices, NOR memory devices), semiconductor memory devices, such as erasable programmable read-only memory (EPROM), electrically erasable programmable read-only memory (EEPROM), compact disc read-only memory (CD-ROM), digital versatile disc read-only memory (DVD-ROM), or other non-volatile solid state storage devices. For example, data storage device 320 may be implemented using memory system 110 (FIG. 1A) described herein. In some examples, data storage device 320 and main memory device 330 may include one or more memory devices 130 (FIG. 1A).

Input/output devices 390 may include peripherals, such as a printer, scanner, display screen, etc. For example, input/output devices 390 may include a display device such as a cathode ray tube (CRT), plasma or liquid crystal display (LCD) monitor for displaying information to a user, a keyboard, and a pointing device such as a mouse or a trackball by which the user can provide input to apparatus 300.

Any or all of the functions of the systems and apparatuses discussed herein may be performed by processor 310, and/or incorporated in, an apparatus or a system such as system 100. Further, system 100 and/or apparatus 300 may utilize one or more neural networks or other deep-learning techniques performed by processor 310 or other systems or apparatuses discussed herein.

One skilled in the art will recognize that an implementation of an actual computer or computer system may have other structures and may contain other components as well, and that FIG. 3 is a high-level representation of some of the components of such a computer for illustrative purposes.

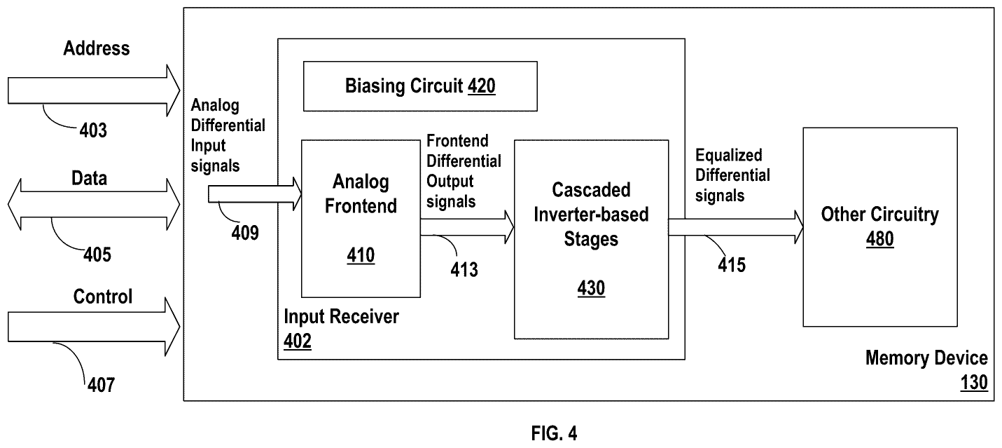

FIG. 4 is a block diagram of an example memory device 130 with an input receiver 402, in accordance with examples as disclosed herein. Input receiver 402 can be, for example, a part of I/O control circuitry 112 as described above in connection with FIG. 1C, or I/O circuitry of another part of memory device 130. As illustrated in FIG. 4, in some examples, memory device 130 includes input receiver 402, and other circuitry 480. It is understood that memory device 130 shown in FIG. 4 is simplified and can include other components described above in connect with FIG. 1C. For example, other circuitry 480 shown in FIG. 4 may include an array of memory cells 104, column decoder 111, row decoder 108, one or more registers 114, 122, and 124, local controller 135, etc., as described above in connection with FIG. 1C. These circuitries are thus not repeatedly described and are omitted from FIG. 4. Other circuitry may also include components that are not described above. For example, other circuitry 480 may include an analog-to-digital converter (ADC) for converting analog signals provided by input receiver 402 to digital signals for further processing.

With continued reference to FIG. 4, in some embodiments, input receiver 402 receives high speed analog differential input signals 409. Typically, signals 409 are data signals and can be transferred at multiple Giga-Hertz frequency range. In differential signals, information is conveyed by the difference between two complementary signals. Differential signaling has the advantage of being able to reject common-mode noise that are unwanted interference that affect both signal lines equally. Therefore, compared to single-ended signaling, differential signaling has a better noise immunity. Differential signaling may also increase a dynamic range of input receiver 402. Differential signaling is often used for high-speed data transfer and less used for transferring low speed address or control signals. As such, in FIG. 4, analog differential input signals 409 may include data signals 405, but not necessarily address signals 403 and control signals 407.

In FIG. 4, input receiver 402 includes an analog frontend 410 configured for receiving the analog differential input signals 409 from external of input receiver 402 or external of memory device 130. For example, the analog differential input signals 409 may be part of data signals 405 sent by an external memory controller (e.g., controller 115) or host. Analog frontend 410 processes the analog input differential signals and generates frontend differential output signals 413. An analog signal represents information as continuously varying voltage, current, or other physical quantities, while a digital signal uses discreate values to represent data. In some examples, a biasing circuit 420 provides biasing voltage and/or biasing current to the analog frontend 410 for setting the proper operational points. Analog frontend 410 amplifies and/or equalizes the analog differential input signals 409, and generates frontend differential output signals 413, which are amplified differential signals. Frontend differential output signals 413 are then provided to cascaded inverter-based stages 430 for further amplification and bandwidth extension. Thus, cascaded inverter-based stage 430 provides continuous-time linear equalization (CTLE) for input receiver 402. CTLE can be used to mitigate the effects of signal distortion and to compensate for the frequency-dependent attenuation and phase distortion of the signals, thereby allowing input receiver 402 to recover the original transmitted signals more accurately. As shown in FIG. 4, cascaded inverter-based stages 430 therefore outputs equalized differential signals 415 to other circuitry 480 of memory device 130 or to another device, for further processing (e.g., digitizing, filtering, storing, or other processes). Analog frontend 410, biasing circuit 420, cascaded inverter-based stages 430 are described in greater detail below.

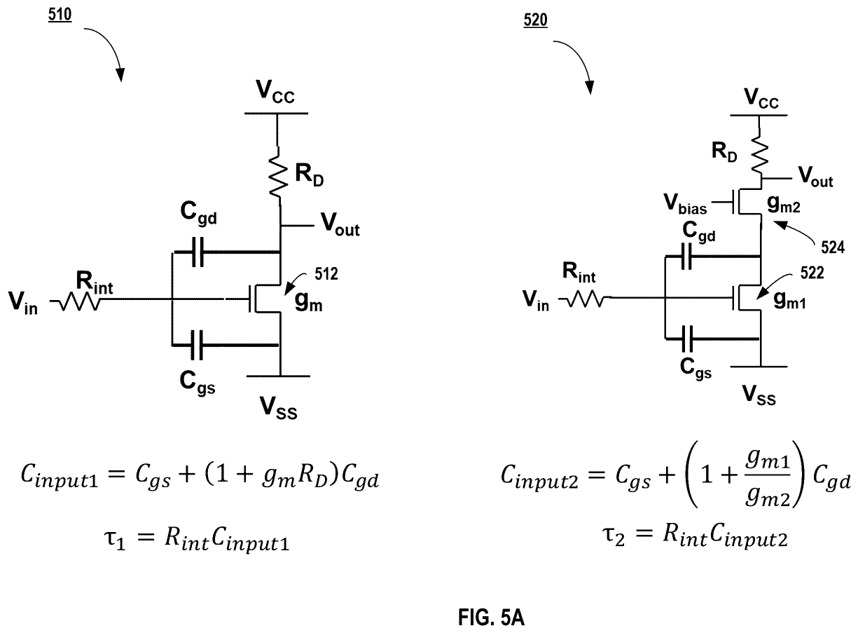

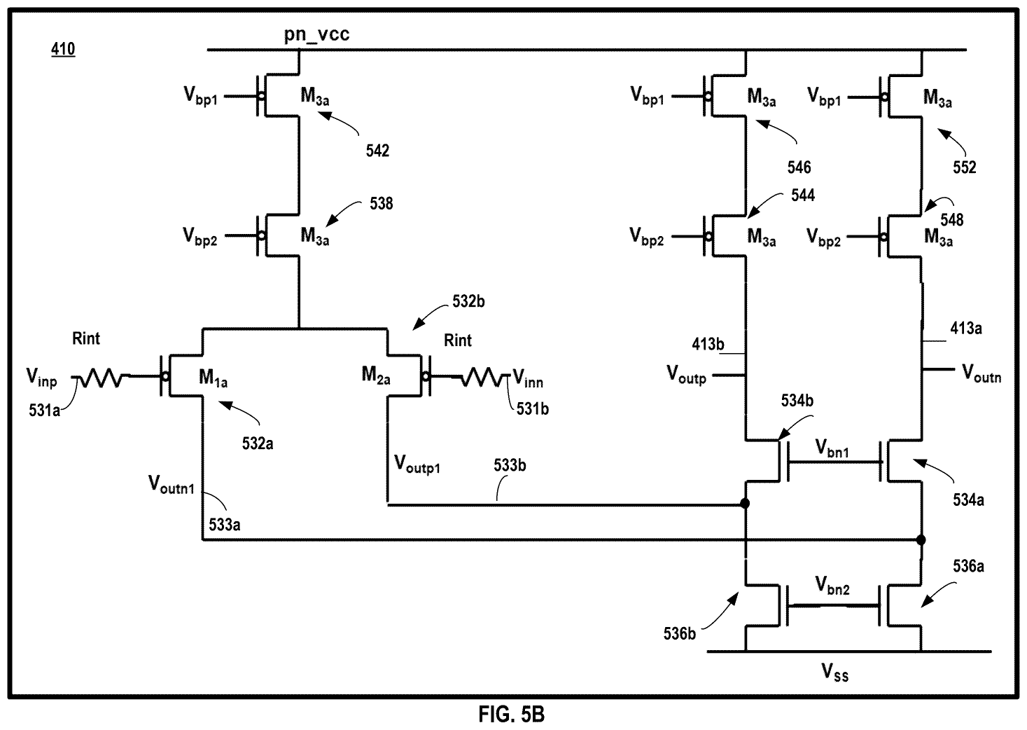

As described above, in one example, analog frontend 410 may include a cascode circuit. FIG. 5A are circuit diagrams illustrating a common source circuit 510 and a cascode circuit 520 for comparison, in accordance with examples as disclosed herein. Both circuits may be used in an input receiver for receiving an input signal. Common source circuit 510, however, has a common source stage Miller effect. As shown in FIG. 5A, circuit 510 includes a transistor 512, which may be a FET (field effect transistor) or another type of transistor. For illustrative purposes, transistor 512 is shown as an NMOS (n-type metal-oxide-semiconductor) transistor, but it may also be a PMOS (p-type MOS) transistor. The gate terminal of transistor 512 receives the input analog signal Vᵢₙ. The source of transistor 512 is coupled to electrical ground denoted by Vₛₛ; and the drain of the transistor 512 is coupled to a power supply denoted by V_{cc}. Circuit 510 also includes a parasitic gate-drain capacitator denoted by C_{gd}, a parasitic gate-source capacitor denoted by C_{gs}, a gate resistor denoted by Rᵢₙₜ, and a drain resistor denoted by R_{D}. These components are associated with the transistor 512 and wires of circuit 510, and may be unintended or undesired parasitic components (capacitance or resistance) that exist in circuit 510. The input capacitance of circuit 510 (i.e., the capacitance when looking into the gate terminal of transistor 512) can be calculated as shown in FIG. 5A and in the below equation [1].

$${C}_{input 1} = {G}_{gs} + ( 1 + {g}_{m} {R}_{D} ) {C}_{gd} \qquad [ 1 ]$$

In equation [1], Cᵢₙₚᵤₜ₁ denotes the input capacitance of circuit 510, C_{gs} denotes the gate-source capacitance, C_{gd} denotes the gate-drain capacitance, gₘ denotes the gain of the transistor 512, and R_{D} denotes the gate resistance. Therefore, the input capacitance is a function of the gain gₘ of the transistor 512. The higher the gain gₘ, the higher the input capacitance. This increase of the input capacitance of the transistor 512 is due to the Miller effect, which refers to the increase of equivalent input capacitance of an amplifier or a transistor when there is voltage gain between the input and output terminals. The Miller effect in turn increases the time constant of the circuit 510 because the time constant is a multiplication of the gate resistance Rᵢₙₜ and the input capacitance Cᵢₙₚᵤₜ₁, as shown below in equation [2].

$$\text{?}$$

$$\text{?} \text{indicates text missing or illegible when filed}$$

In the above equation [2], τ₁ denotes the time constant, Cᵢₙₚᵤₜ₁ denotes the input capacitance of circuit 510, and Rᵢₙₜ denotes the gate resistance. The increase of the time constant reduces the bandwidth of the circuit 510, and in turn the bandwidth of the input receiver.

To mitigate the Miller effect of a common source circuit 510, a cascode circuit 520 may be used. Cascode circuit 520 includes two transistors 522 and 524 connected in series. FIG. 5A illustrates the cascode circuit 520 using NMOS transistors, but PMOS or other types of transistors can also be used to form a cascode circuit. In circuit 520, the source terminal of transistor 522 is coupled to electrical ground denoted by Vₛₛ; the drain terminal of transistor 522 is coupled to the source terminal of transistor 524; and the gate terminal of transistor receives the input signal Vᵢₙ. The gate terminal of transistor 524 is coupled to another biasing circuit to receive a biasing voltage V_{bias} for setting the proper operating point of circuit 520. The drain terminal of transistor 524 is coupled to the power supply denoted by V_{cc}. Parasitic components of circuit 520 are also shown, including parasitic gate-drain capacitor C_{gd}, parasitic gate-source capacitor C_{gs}, gate resistor Rᵢₙₜ, and drain resistor R_{D}. The input capacitance Cᵢₙₚᵤₜ₂ of cascode circuit 520 is calculated as shown in FIG. 5A and in the below equation [3].

$${C}_{input 2} = {C}_{gs} + ( 1 + \frac{{g}_{m 1}}{{g}_{m 2}} ) {C}_{gd} \qquad [ 3 ]$$

In the above equation [3], Cᵢₙₚᵤₜ₂ denotes the input capacitance of cascode circuit 520, C_{gs} denotes the gate-source capacitance, C_{gd} denotes the gate-drain capacitance, gₘ₁ denotes the gain of the transistor 522, gₘ₂ denotes the gain of the transistor 524, and Rp denotes the gate resistance. The time constant τ₂ of the cascode circuit 520 can be calculated as below using equation [4]

$${τ}_{2} = {R}_{int} {C}_{input 2} \qquad [ 4 ]$$

Based on the above equations [3] and [4], the Miller effect of a common source circuit 510 can be mitigated by using cascode circuit 520. The input capacitance of circuit 520 is a function of the ratio of the gain of transistor 522 (denoted by gₘ₁) and the gain of transistor 524 (denoted by gₘ₂). Therefore, by properly configuring the ratio of the gains of the two transistors 522 and 524, the input capacitance Cᵢₙₚᵤₜ₂ can be set to be much smaller than Cᵢₙₚᵤₜ₁. In turn, the time constant τ₂ of cascode circuit 520 can be greatly reduced compared to the time constant τ₁ of common source circuit 510. The cascode circuit 520 can thus enable an input receiver to have a higher bandwidth and an improved high-frequency performance.

FIG. 5B is a circuit diagram of an analog frontend 410 that can be used in an input receiver 402 shown in FIG. 4. Analog frontend 410 includes a folded cascode circuit having an input transistor pair 532a-532b (collectively input transistor pair 532), cascode transistors 534a-534b (collectively cascode transistors 534), and other biasing and/or current source transistors (e.g., 536a-536b, 538, 542, 544, 546, 548, 552). A folded cascode circuit is an extension of the cascode circuit 520 described above, and can include two or more cascode stages connected in a folded arrangement. Each cascode stage includes a series combination of transistors, usually composed of a lower transistor acting as an input device (common-emitter or common-source transistor) and an upper transistor acting as a cascode device (common-base or common-gate transistor). In a folded cascode arrangement, the output of the first cascode stage is folded back and connected to the input of the subsequent cascode stage. This creates a series connection of the cascaded cascode stages, enabling the reduction of the Miller effect and improving the bandwidth of the input receiver. In the arrangement shown in FIG. 5B, the input transistor pair 532a-532b is the first cascode stage and the output signals 533a-533b of the first cascode stage are folded and connected to the input of the second cascode stage including cascode transistors 534a-534b.

In the example shown in FIG. 5B, analog frontend 410 has an input transistor pair 532a and 532b (collectively as input transistor pair 532). The input transistor pair 532 is configured to receive, at the gate terminals, analog differential input signals Vᵢₙₚ 531a and Vᵢₙₙ 531b (e.g., corresponding to signals 409 shown in FIG. 4) from external of the input receiver or the I/O circuit (e.g., from a memory system controller). The input transistor pair 532, in the example shown in FIG. 5B, includes PMOS (p-type metal-oxide-semiconductor) transistors. The gate terminals of the input transistor pair 532 receive analog differential input signals. The source terminals of the input transistor pair 532 are coupled to the power supply (denoted by pn_Vcc) via transistors 538 and 542. The drain terminals of the input transistor pair 532 are folded and connected to the source terminals of the cascode transistors 534. It is understood that the input transistor pair 532 can also be NMOS transistors or other types of transistors, with the proper configuration change of the cascode transistors. The use of PMOS or NMOS transistors of the input transistor pair 532 depends on the common mode voltage of the input signals and possibly other factors. For example, PMOS transistors may be used when the common mode voltage of the input signals may have a range close to the ground voltage (denoted by Vₛₛ in FIG. 5B), while NMOS transistors may be used when the common mode voltage of the input signals may have a range close to the power supply voltage (denoted by pn_Vcc in FIG. 5B).

The differential output signals Vₒᵤₜₙ₁ 533a and Vₒᵤₜₚ₁ 533b from the input transistor pair 532 are folded and connected to the source terminals of cascode transistors 534a and 534b, respectively; and connected to the drain terminals of the current source transistors 536a and 536b, respectively. Cascode transistors 534a and 534b have a common gate terminal. The drain terminals of cascode transistors 534 provide the output differential signals of the analog frontend 410, and are coupled to the power supply denoted by pn_Vcc via biasing and/or current sourcing transistors 544, 546, 548, and 552, as shown in FIG. 5B. Source terminals of cascode transistors 534a and 534b are coupled to the drain terminals of the current source transistors 536a and 536b, respectively, which in turn are coupled to electrical ground denoted by Vₛₛ. The current source transistors 536a and 536b have a common gate terminal, which is provided with a biasing voltage V_{bn1} from a biasing circuit (described below in greater detail). The biasing voltage V_{bn1} sets a proper operating point of the cascode transistors and provides a current to the cascode transistors 534. The cascode transistors 534 can be properly sized and biased such that the ratio of the gains of the input transistor pair 532 and cascode transistors 534 is configured to reduce or minimize the Miller effect, similar to those described above in connection with FIG. 5A. Cascode transistors 534, together with biasing/current sourcing transistors 536, 544, 546, 548, and 552, can also be properly sized and biased to provide the desired common mode of the frontend differential output signals 413 (including signals 413a and 413b). For illustrative purposes, the biasing/current sourcing transistors 544, 546, 548, and 552 are shown as PMOS transistors and the current sourcing transistors 536 are shown as NMOS transistors. It is understood that NMOS/PMOS or other transistors may be used, depending on the overall configuration of the folded cascode circuit of analog frontend 410 and the common mode requirement for the input differential signals 531 and differential output signals 413.

In FIG. 5B, analog frontend 410, by using a folded cascode circuit configuration, generates the differential output signals 413, which may have a higher amplitude and improved eye opening compared to the input differential signals 531. In other words, by using and properly configuring the folded cascode circuit, analog frontend 410 can reduce or minimize the Miller effect to improve the bandwidth (by reducing the time constant). Analog frontend 410 can achieve a higher gain due to the cascode circuit, thereby providing a higher output signal amplitude and an improved eye opening. Analog frontend 410 can also be configured to have a wider input signal range by, for example, using PMOS as the input transistor pair and can thus operate with a low power supply (denoted by pn_Vcc), of e.g., 1.6V. In analog frontend 410, one of the inputs can be a reference DC voltage (denoted by V_{ref} or V_{refbias}) and the other input can be a time varying signal. This can introduce distortion if the tail current source is not ideal. A cascode tail current source (e.g., 538 and 542 in FIG. 5B) is used to reduce the distortion due to noise on the reference voltage (V_{ref}). A bias circuit is used to generate the biases of cascode tail current source. The analog frontend 410 can tolerate reference voltage changes and therefore, making analog frontend 410 more robust.

Furthermore, the folded cascode configuration of analog frontend 410 uses only a single stage compared to a frontend having multiple stages of common source configurations. The latter configuration has a limited bandwidth, higher gate resistance of the input transistors, a high sensitivity to reference voltage changes, and a high likelihood of failure when operating under a low power supply voltage. In contrast, analog frontend 410 can avoid these limitations of a multiple stage common source configuration. Analog frontend 410 further provides a high output impedance, which reduces the need of common mode feedback (CMFB). CMFB is used to regulate the common-mode voltage of a differential amplifier, a differential transistor pair, or other differential circuitry. The common-mode voltage is the average voltage between the two input terminals of a differential amplifier or a differential transistor pair. CMFB is employed to ensure that the common-mode voltage remains within a specified range, providing better performance and stability in certain applications. As described above, the circuit configurations of analog frontend 410 have greater ability to tolerate common mode shifts and therefore reduces the need for CMFB. In some examples, the common mode voltage of the output signals 413 of analog frontend 410 shown in FIG. 5B can be set at the trip point of the subsequent inverter-based stage coupled to analog frontend 410, reducing the duty cycle variation or distortion. The inverter-based stages and the improvement of the duty cycle are described in greater detail below.

In some embodiments, analog frontend 410 with the folded cascode circuit can be adjusted to change its operational speed and/or power consumption. For example, fuses in an ROM (read-only memory) can be used to control the operations of analog frontend 410 to achieve the adjustments.

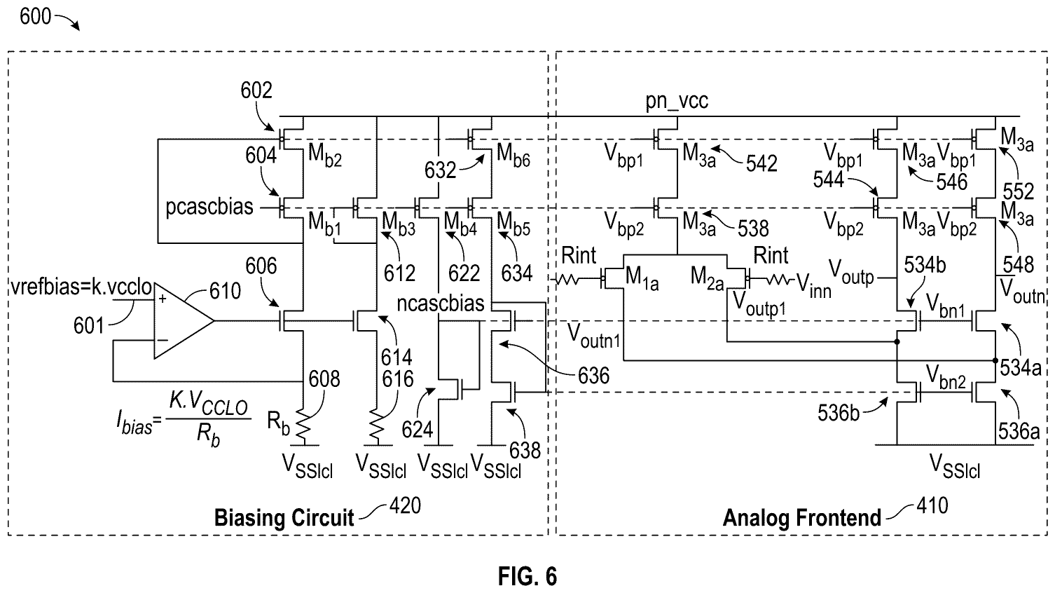

As described above, analog frontend 410 includes several biasing/current source transistors that provide biasing voltages and/or currents to the input transistor pair and the cascode transistors. The gate terminals of these biasing/current source transistors receive the biasing voltages from a biasing circuit 420. FIG. 6 is a circuit diagram of an example biasing circuit 420 configured to control biasing voltages of analog frontend 410, in accordance with examples as disclosed herein. Biasing circuit 420, by controlling the biasing voltages of the various transistors in analog frontend 410, sets the operating points of analog frontend 410. For example, by providing the proper biasing voltages, the common mode voltages of the input transistor pair and the cascode transistors in analog frontend 410 can be properly set for optimizing the operations (e.g., set the common mode voltage at the trip point of the inverter-based stage coupled to analog frontend 410). The two analog differential input signals 531 thus have the same common mode voltages (also referred to as DC signal voltages) and opposite polarities of differential mode voltages (also referred to as small signal voltages or AC signal voltages). Similarly, the two frontend differential output signals have the same common mode voltages and opposite polarities of differential mode voltages.

With continued reference to FIG. 6, biasing circuit 420, in some examples, includes several branches. The first branch includes transistors 602 (e.g., an PMOS denoted by M_{b2}), 604 (e.g., an PMOS denoted by M_{b1}), 606 (e.g., an NMOS), and a resistor 608 (denoted by R_{b}). In this example, the source terminal of transistor 602 is coupled to a power supply (denoted by pn_vcc), which may be the same as the power supply used for the analog frontend 410. The drain terminal of transistor 602 is coupled to the source terminal of transistor 604, and therefore the two transistors are connected in series. The gate terminal of transistor 602 is coupled to the drain terminal of transistor 604. The gate terminal of transistor 606 is coupled to an output of an operational amplifier 610 (op-amp 610). Op-amp 610 receives a reference voltage 601 (denoted as V_{refbias}) at one input terminal (e.g., the positive input terminal) of op-amp 610. Op-amp 610's other input terminal (e.g., the negative input terminal) is coupled to the source terminal of transistor 606 and a first terminal of resistor 608. The the source terminal of transistor 606 and a first terminal of resistor 608 are coupled together. The second terminal of transistor 606 is coupled to electrical ground denoted by V_{sslcl}. Op-amp 610 can be configured to have a high input impedance and low output impedance, and have a high-gain. Op-amp 610 is configured in a closed-loop configuration as shown in FIG. 6, such that the biasing current (denoted by I_{bias}) in the first branch is the reference voltage divided by resistor 608 (i.e., I_{bias}=V_{refbias}/R_{b}). The reference voltage V_{refbias} can be designed to have a value k*V_{cclo}, i.e., a fraction of the power supply voltage V_{cclo}. Therefore, the biasing current I_{bias} can be calculated as I_{bias}=k*V_{cclo}/R_{b}, wherein k is a positive number between 0 and 1.

With continued reference to FIG. 6, the second branch of biasing circuit 420 includes transistors 612 (e.g., a PMOS denoted by M_{b3}), 614 (e.g., an NMOS), and a resistor 616 (denoted by R_{b}). In this example, the source terminal of transistor 612 is coupled to a power supply (denoted by pn_vcc), which may be the same as the power supply used for the analog frontend 410. The drain terminal of transistor 612 is coupled to the drain terminal of transistor 614. Further more, the drain terminal and the gate terminal of transistor 612 are coupled together, forming a diode connection. Transistor 612 thus operates like a diode. The gate terminal of transistor 614 is coupled to the gate terminal of transistor 606 in the first branch and also coupled to the output of op-amp 610. The source terminal of transistor 614 is coupled to the first terminal of resistor 616. The second terminal of resistor 616 is coupled to electrical ground (denoted by V_{sslcl}).

At least the first branch of biasing circuit 420 can be configured to function as a current generator configured to generate a biasing current (denoted by I_{bias}) and operate to set the biasing voltages for the PMOS transistors in the analog frontend 410. As described above, the biasing current I_{bias} is set based on the reference voltage V_{refbias}, and the value of resistor 608. Based on the biasing current, the biasing voltages of PMOS transistors 602 and 604 can be set. The second branch of biasing circuit 420 can be configured to function as a current mirror. Because the gate terminals of transistors 604 and 612 are coupled together, they have the same biasing voltage. Similarly, the gate terminals of transistors 606 and 614 are coupled together, and therefore they have the same biasing voltage. Therefore, the biasing current I_{bias} can be mirrored to the second branch. Further, the gate terminal of transistor 602 of the first branch is coupled to the gate terminals of transistors 542, 546, and 552 of the analog frontend 410; and the gate terminal of transistor 604 (and transistor 612) is coupled to the gate terminals of transistors 538, 544, and 548. The transistors having gate terminals coupled together are matches in size and therefore, the biasing voltages are provided to the PMOS transistors of analog frontend 410 from biasing circuit 420 for setting the proper operation points. As shown in FIG. 6, a biasing voltage provided by the first branch can be denoted by pcascbias in biasing circuit 420 and V_{bp2} in analog frontend 410; and another biasing voltage is denoted by V_{bp1} in analog frontend 410. These biasing voltages are for biasing the PMOS transistors in analog frontend 410.

The third branch and the fourth branch of the biasing circuit 420 are configured to function as current mirrors to provide biasing voltages to the NMOS transistors in analog frontend 410. As shown in FIG. 6, the third branch of biasing circuit 420 includes transistors 622 (e.g., an PMOS denoted by M_{b4}), and 624 (e.g., an NMOS). In this example, the source terminal of transistor 622 is coupled to a power supply (denoted by pn_vcc), which may be the same as the power supply used for the analog frontend 410. The drain terminal of transistor 622 is coupled to the drain terminal of transistor 624. The gate terminal of transistor 622 is coupled to the gate terminals of transistors 604 and 612. The drain terminal and gate terminal of transistor 624 are coupled together to form a diode connection. Therefore, transistor 624 operates like a diode.

The fourth branch of biasing circuit 420 includes transistors 632 (e.g., an PMOS denoted by Mb6), 634 (e.g., an PMOS denoted by Mb5), 636 (e.g., an NMOS), and 638 (e.g., an NMOS). In this example, the source terminal of transistor 632 is coupled to a power supply (denoted by pn_vcc), which may be the same as the power supply used for the analog frontend 410. The drain terminal of transistor 632 is coupled to the source terminal of transistor 634. The gate terminal of transistor 632 is coupled to the gate terminals of transistors 602. The gate terminal of transistor 634 is coupled to the gate terminals of transistors 604, 612, and 622. The drain terminal of transistor 634 is coupled to the drain terminal of transistor 636. The gate terminal of transistor 636 is coupled to the gate terminal of transistor 624 in the third branch. The source terminal of transistor 636 is coupled to the drain terminal of transistor 638. The source terminal of transistor 638 is coupled to the electrical ground (denoted by V_{sslcl}). The gate terminal of transistor 638 and the drain terminal of transistor 636 are coupled together.

The third branch and the fourth branch of the biasing circuit 420 are configured to function as current mirrors and provide biasing voltages to the NMOS transistors of analog frontend 410. As shown in FIG. 6, the size of the transistors 622 and 634 are matched to that of transistors 604 and 612, and similarly the transistors 632 and 602 may be matched in size. As a result, the biasing current (denoted by I_{bias}) generated by the first branch may be mirrored to the third and fourth branches. The voltages of the gate terminals of transistors 636 and 638 may thus be set according to the mirrored biasing current. Further, the gate terminal of transistor 636 of the fourth branch is coupled to the gate terminals of transistors 534a and 534b of the analog frontend 410, thereby providing the biasing voltage denoted by V_{bn1} to cascode transistors 534. The gate terminals of transistor 638 is coupled to the gate terminals of transistors 536a and 536b, thereby providing the biasing voltage denoted by V_{bp1} to current source transistors 536. The transistors having gate terminals coupled together are matches in size and therefore, the biasing voltages are provided to the PMOS transistors of analog frontend 410 from biasing circuit 420 for setting the proper operation points. As shown in FIG. 6, a biasing voltage provided by the fourth branch of biasing circuit 420 can be denoted by ncascbias in biasing circuit 420 and V_{bn1} in analog frontend 410; and another biasing voltage is denoted by V_{bn2} in analog frontend 410. These biasing voltages are for biasing the NMOS transistors in analog frontend 410.

The configuration shown in FIG. 6 has a biasing circuit 420 that is configured such that the common mode of the folded cascode circuit of analog frontend 410 is biased based on termination with respect to ground. Termination in high-speed signal communication refers to the use of electrical components (e.g., resistors, capacitors, and/or inductors) to properly terminate transmission lines and minimize signal reflections. The termination can be configured to terminate with respect to electrical ground or the power supply. If the termination is configured to be with respect to the electrical ground, the circuit needs to be biased at an operation point (e.g., a common mode voltage) that is close to the ground. For example, the termination may require that the operation point to be approximately ⅙ of the power supply voltage. In some examples, the operation point may be set at approximately ½ of the power supply voltage. The folded cascode circuit described above can be configured to have common mode voltage biased close to the ground voltage (e.g., 0V or ⅙ of the power supply voltage). Therefore, the biasing circuit 420 can be configured accordingly. In some examples, in the first branch, the resistor 608 is a tunable resistor such that the resistance can be changed. As a result, the biasing current can be changed, and biasing voltages can be changed too. Biasing circuit 420 can therefore be tunable based on the termination schemes and/or other requirements of analog frontend 410.

The biasing circuit 420 described above can have a fast-settling time (e.g., less than 5 ns), such that the analog frontend 410 can be provided with biasing voltages quickly for it to properly operate. Biasing circuit 420 can be designed to be tunable and therefore configured according to different requirements of the input receiver (e.g., the bandwidth, speed, input dynamic range, termination, etc.). The biasing circuit 420 can also be designed to minimize the power consumption.

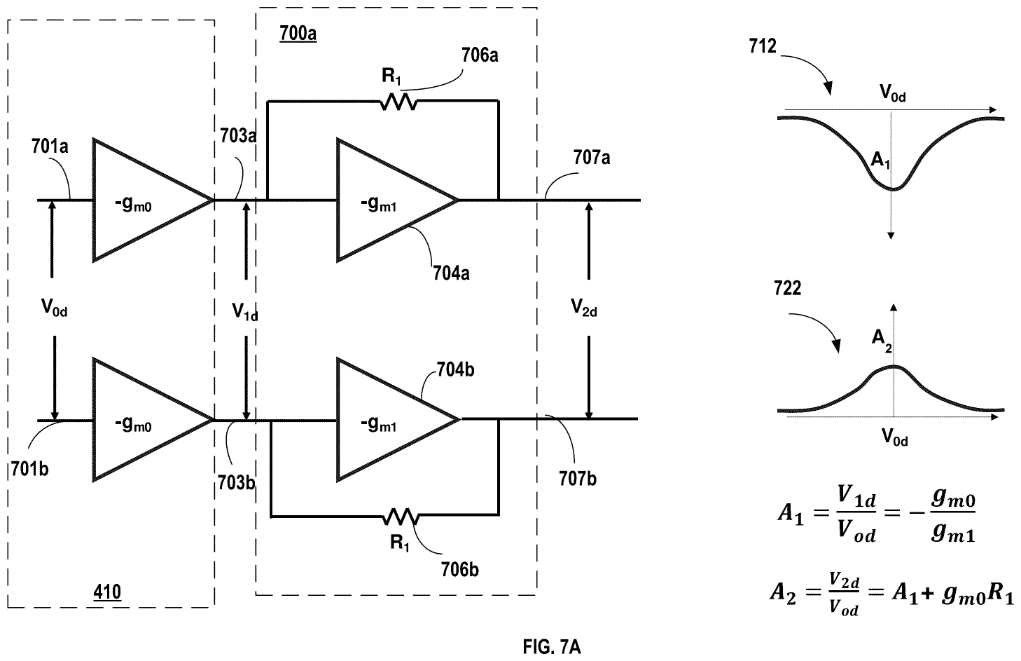

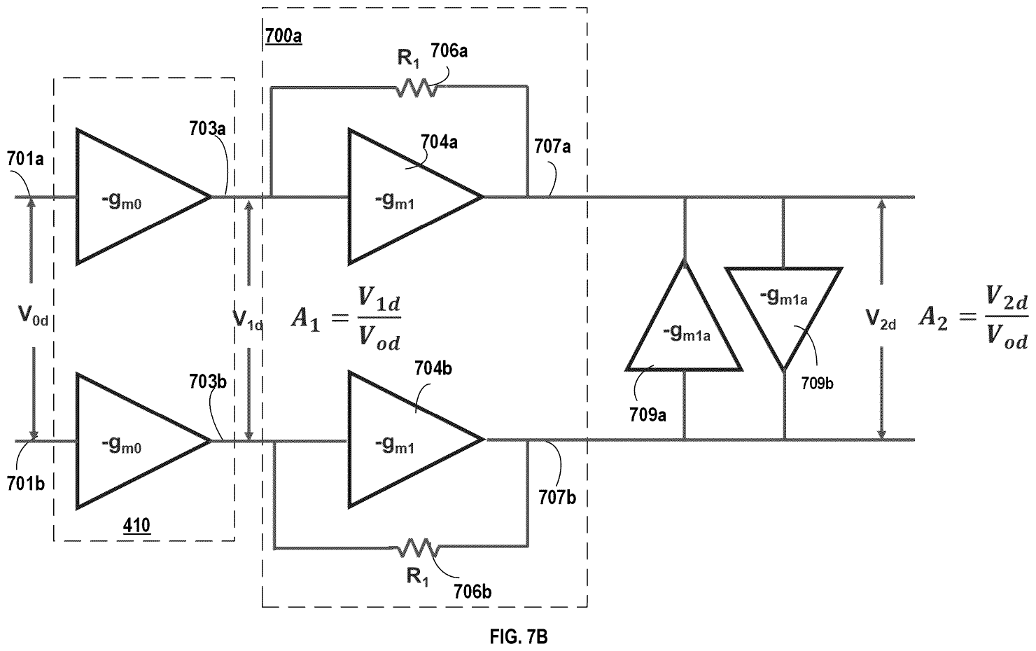

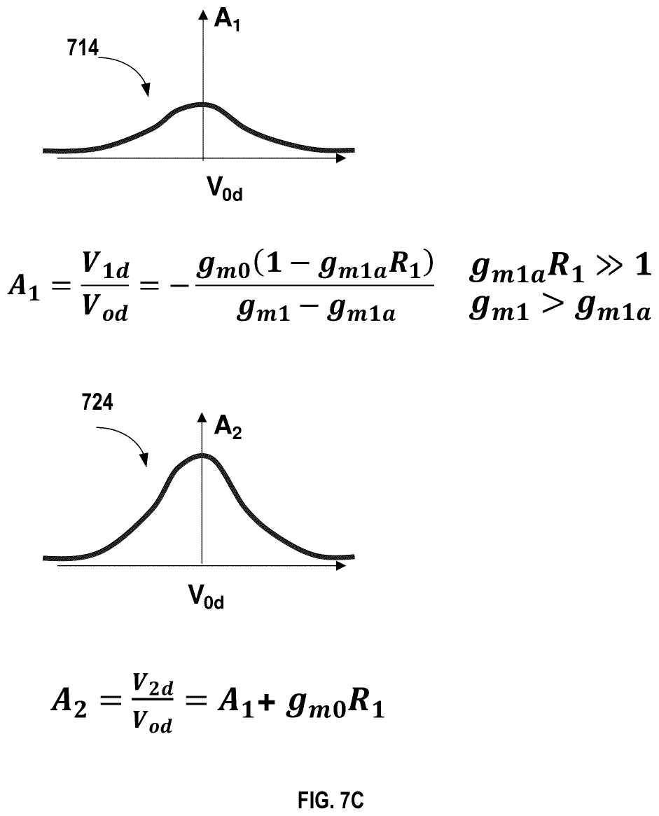

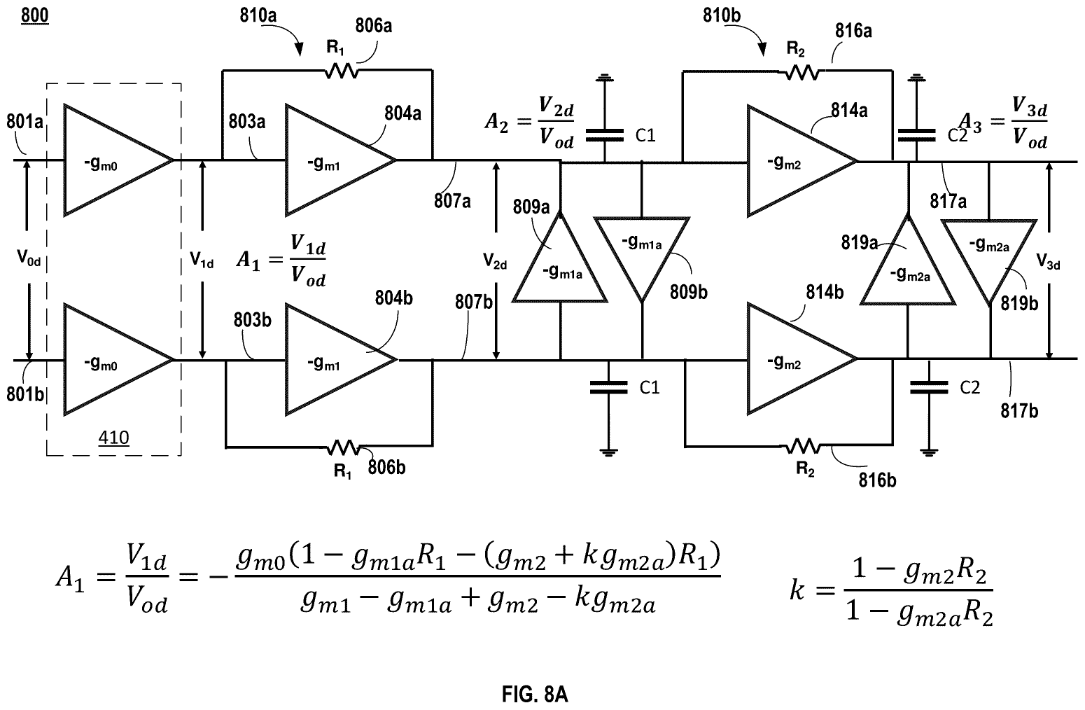

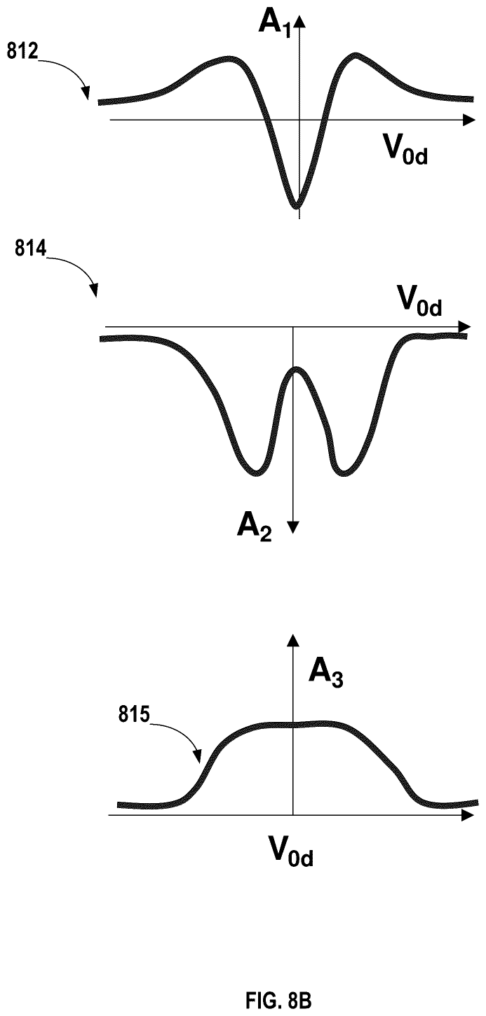

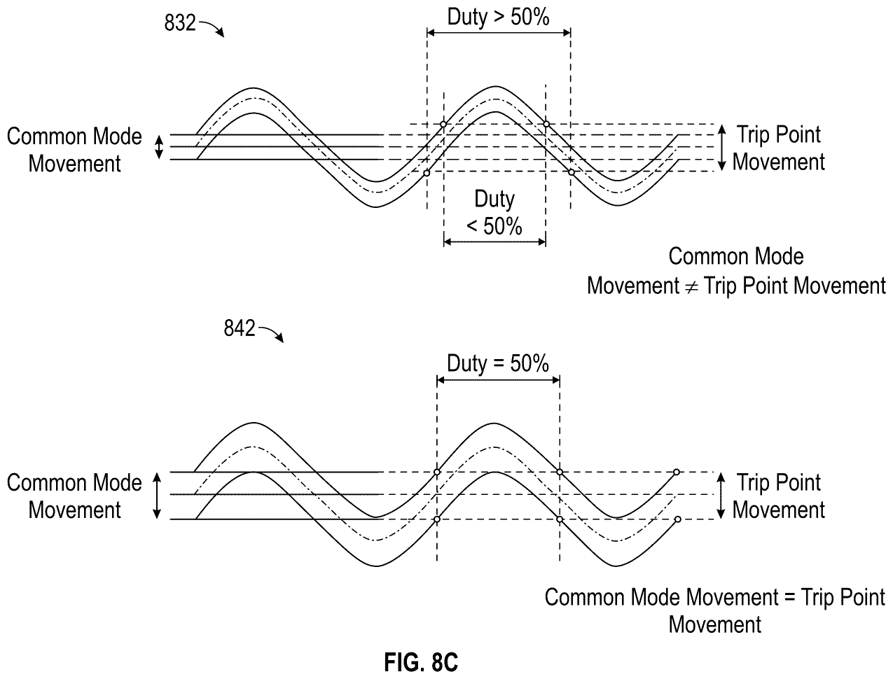

With reference briefly back to FIG. 4, analog frontend 410 generates frontend differential output signals 413, which are received by cascaded inverter-based stages 430. Cascaded inverter-based stages 430 include multiple inverter-based stages cascaded together. FIG. 7A is a block diagram of a single inverter-based stage 700a, in accordance with examples as disclosed herein. FIG. 7A, and similarly FIG. 7B and FIG. 8A, illustrate two signal paths for differential signals and the below descriptions may only refer to one of the signal paths of the differential signals with the understanding that the other signal path operates in a similar way. In FIG. 7A, analog frontend 410 receives analog differential input signals 701a and 701b. The difference between the signals 701a and 701b is a differential mode input voltage and is denoted by V_{0d}. As described above, analog frontend 410 may include a folded cascode circuit and a biasing circuit. Analog frontend 410 amplifies the difference of the input signals 701a and 701b and provides frontend differential output signals 703a and 703b (collectively as signals 703). The difference between the signals 703a and 703b is a differential mode frontend output voltage and is denoted by V_{1d}. The amplification gain, or simply the gain, of analog frontend 410 (denoted by A₁) is therefore the ratio between the differential mode frontend output voltage and differential mode input voltage. The gain is expressed as A₁=V_{1d}/V_{0d}=−gₘ₀/gₘ₁.

Frontend differential output signals 703 are provided to an inverter-based stage 700a. An inverter-based stage 700a may include one or more inverter circuits 704a and 704b. An inverter circuit typically includes a PMOS transistor and an NMOS transistor connected in series. The drain terminal of the PMOS transistor may be connected to a power supply and the source terminal of the NMOS transistor may be connected to an electrical ground. In some examples, each of the PMOS and the NMOS transistors is diode-connected such that they operate like a diode. Thus, the gate terminal of the PMOS transistor is coupled to the source/drain terminal of the PMOS transistor; and similarly, the gate terminal of the NMOS transistor is coupled to the source/drain terminal of the NMOS transistor. The inverter-based stage 700a further includes feedback resistors 706a and 706b (denoted by R₁, collectively as 706).

As shown in FIG. 7A, the feedback resistor 706a forms a feedback path from the output of the inverter-based stage 700a to the input of the inverter-based stage 700a. This kind of configuration is also referred to as an active inductor and can be used to smooth the gain of the overall system across the input signal voltage range. As illustrated in FIG. 7A, waveform 712 shows a waveform of gain A₁ as a relation to the differential mode input voltage V_{0d}. The differential mode input voltage V_{0d} can be swept from low to high (e.g., from 0V to the power supply voltage), and the gain A₁ can be measured, thereby obtaining a gain profile. The gain A₁ is the ratio of the differential mode frontend output voltage Via to the differential mode input voltage V_{0d}, i.e., A₁=V_{1d}/V_{0d}. In the system shown in FIG. 7A, A₁=−gₘ₀/gₘ₁, wherein gₘ₀ is the gain of the analog frontend 410, and gₘ₁ is the gain of the inverter-based stage 700a. Waveform 712 shows that the gain A₁ varies when the differential mode input voltage V_{0d} varies and there may be a peak of gain A₁ at a particular value of V_{0d}. In other words, the gain A₁ may not be smooth or flat, and may vary significantly, when differential mode input voltage V_{0d} varies. This is typically undesirable because the eye opening of frontend differential output signals 703 may be worse with the significant variation of the gain A₁.

FIG. 7A also shows another waveform 722, which is a relation between a gain A₂ and the differential mode input voltage V_{0d}. Similar to measuring gain A₁, the differential mode input voltage V_{0d} can be swept from low to high (e.g., from 0V to the power supply voltage), and the gain A₂ can be measured. The amplification gain A₂ is the ratio of the inverter-based stage 700a's differential mode output voltage V_{2d} to the differential mode input voltage V_{0d}, i.e., A₂=V_{2d}/V_{0d}. In the system shown in FIG. 7A, A₂=A₁+gₘ₀*R₁, wherein gₘ₀ is the gain of the analog frontend 410, and R₁ is the value of the feedback resistor in inverter-based stage 700a. Waveform 722 shows that while gain A₂ still varies when the frontend differential mode input voltage V_{0d} varies and there may also be a peak of gain A₂ at a particular value of V_{0d}, the range of variation of gain A₂ is smaller than that of gain A₁. In other words, due to the configuration of the inverter-based stage 700a with the feedback resistor R₁, the profile of gain A₂ may be much more linear or flat, compared to the profile of gain A₁. The peak value of gain A₂ is typically also smaller than that of gain A₁. An improved linearity and flatter gain profile across the voltage range of the differential mode input voltage V_{0d} is typically desirable, because it reduces jitter and improves the eye opening of the output signals 707.

FIG. 7B is a block diagram of an inverter-based stage 700a with a pair of cross-coupled inverters 709a and 709b, in accordance with examples as disclosed herein. The inverter-based stage 700a and frontend 410 are described above and thus not repeated. In FIG. 7B, after the inverter-based stage 700a, a pair of cross-coupled inverters 709a and 709b (collectively as 709) is used. The cross-coupled inverters 709 are configured such that the output of inverter 709a is coupled to the input of inverter 709b, and vice versa. The cross-coupled inverters 709a and 709b are disposed between the two differential output signals 707a and 707b of the inverter-based stage 700a. The cross-coupled inverters 709a and 709b form a positive feedback loop between the differential output signals 707a and 707b. As discussed above, differential signals have opposite polarities (e.g., one negative and one positive relative to a common mode voltage, or a high state or a low state). The cross-coupled inverters 709a and 709b create a bistable state, improving the stability of the differential output signals 707a and 707b such that they maintain their polarities (e.g., high or low) due to the feedback loop. In addition, the cross-coupled inverters 709 can also boost the amplification gain of the system shown in FIG. 7B at high frequencies.

FIG. 7C illustrates two waveforms 714 and 724 showing the variation of gain A₁ and gain A₂, respectively, when the differential mode input voltage V_{0d} varies across a voltage range. Waveform 714 is a relation between a gain A₁ and the differential mode input voltage V_{0d}. For measuring gain A₁, the differential mode input voltage V_{0d} can be swept from low to high (e.g., from 0V to the power supply voltage), and the gain A₁ can be measured. The amplification gain A₁ is the ratio of the frontend differential mode output voltage to the frontend differential mode input voltage, i.e., A₁=V_{1d}/V_{0d}. In the system shown in FIG. 7B, A₁ is calculated based on the below equation [5].

$${A}_{1} = \frac{{V}_{1 d}}{{V}_{o d}} = - \frac{{g}_{m 0} ( 1 - {g}_{m 1 a} {R}_{1} )}{{g}_{m 2} - {g}_{m 1 a}} \qquad [ 5 ]$$

In the above equation [5], gₘ₀ is the gain of the analog frontend 410, gₘ₁ is the gain of the inverter-based stage 700a, and gₘ₁ₐ is the gain of the cross-coupled inverters 709, and R₁ is the value of the feedback resistor in inverter-based stage 700a. In equation [5],

gₘ₁ₐR₁>>1 and gₘ₁>gₘ₁ₐ

Waveform 714 shows a relation between gain A₁ and the differential mode input voltage V_{0d}. Similarly, waveform 724 shows a relation between gain A₂ and the differential mode input voltage V_{0d}. The amplification gain A₂ is the ratio of the inverter-based stage 700a's differential mode output voltage to the frontend differential mode input voltage (i.e., A₂=V_{2d}/V_{0d}), when stage 700a has a cross-coupled inverter pair. In the system shown in FIG. 7B, A₂ is calculated based on the below equation [6].

$${A}_{2} = \frac{{V}_{2 d}}{{V}_{od}} = {A}_{1} + {g}_{m 0} {R}_{1} \qquad [ 6 ]$$

Comparing the waveforms 714 and 724, when adding a cross-coupled inverter pair 709, while both gains A₁ and A₂ vary when the frontend differential mode input voltage V_{0d} varies and each of waveforms 714 and 724 may have a peak of gain at a particular value of V_{0d}, the range of variation of gain A₁ is smaller than that of gain A₂. As described above, a smoother and flatter gain profile across the voltage range of the differential mode input voltage V_{0d} is typically desirable, because it improves the eye opening of the output signals. Thus, further improvements of the configuration shown in FIG. 7B can be implemented to make the gain profile of A₂ smoother, by using multiple cascaded inverter-based stages with cross-coupled inverter pairs, as described below.

FIG. 8A is a block diagram of an input receiver 800 having cascaded inverter-based stages with multiple pairs of cross-coupled inverters, in accordance with examples as disclosed herein. Similar to those described above, input receiver 800 has an analog frontend 410 coupled to a first inverter-based stage 810a, which in turn is coupled to a first pair of cross-coupled inverters 809a and 809b (collectively as 809). For input receiver 800, it further includes a second inverter-based stage 810b and a second pair of cross-coupled inverter circuits 819a and 819b (collectively as 819). First inverter-based stage 810a comprises a first pair of inverter circuits 804a and 804b coupled to the analog frontend 410 to receive the frontend differential output signals 803a and 803b (collectively as 803), amplify the frontend differential output signals 803, and output first amplified differential signals 807a and 807b (collectively as 807). The first inverter-based stage 810a thus has a first amplification gain denoted by gₘ₁. And each of the inverter circuit 804a and 804b of the first inverter-based stage 810 has a feedback resistor 806a and 806b, respectively. The feedback resistor 806a or 806b connects the input and output of a respective inverter circuit 804a or 804b, and provides a feedback path of the respective inverter circuit 804a or 804b. Inverter-based stage 810a can be the same or similar to inverter-based stage 700a described above, and therefore is not repeatedly described.

FIG. 8A further shows that a first pair of cross-coupled inverter circuits 809a and 809b (collectively as 809) are coupled between the first amplified differential signals 807a and 807b. Each of the first pair of inverter circuits 809a and 809b has a first amplification gain (denoted by gₘ₁ₐ). The first pair of cross-coupled inverter circuits 809 can be the same or similar to cross-coupled inverter circuits 709 described above, and therefore is not repeatedly described. For example, cross-coupled inverter circuits 809 can boost the amplification of the first inverter-based stage 810a at high frequencies. In some examples, cross-coupled inverter circuits 809 is optional.

FIG. 8A further illustrates that a second inverter-based stage 810b is coupled to the first inverter-based stage 810a and the optional cross-coupled inverter circuits 809. Second inverter-based stage 810a comprises a second pair of inverter circuits 814a and 814b coupled to the first pair of inverter circuits 804a and 804b, respectively, to receive the first amplified differential signals 807a and 807b. The second pair of inverter circuits 814a and 814b further amplify the differential signals 807a and 807b, and output second amplified differential signals 817a and 817b (collectively as 817), respectively. The second inverter-based stage 810b thus has a second amplification gain denoted by gₘ₂. The second amplification gain gₘ₂ may or may not be equal to the first amplification gain gₘ₁. In some examples, second amplification gain gₘ₂ may be smaller than the first amplification gain gₘ₁, such that the second inverter-based stage 810b does not add too much amplification gain to the overall input receiver 800.

As shown in FIG. 8A, similar to those in the first inverter-based stage 810a, each of the inverter circuit 814a and 814b of the second inverter-based stage 810b has a feedback resistor 816a and 816b (denoted by R₂), respectively. The feedback resistor 816a or 816b connects the input and output of a respective inverter circuit 814a or 814b, and provides a feedback path of the respective inverter circuit 814a or 814b. The second inverter-based stage 810b can be the same or similar to inverter-based stage 700a described above, and therefore is not repeatedly described. The feedback resistor 816 used in the second inverter-based stage 810b may have a same or different value than the feedback resistor 806 used in the first inverter-based stage 810a (i.e., R₁ may or may not be equal to R₂).

FIG. 8A further shows that a second pair of cross-coupled inverter circuits 819a and 819b (collectively as 819) are coupled between the second amplified differential signals 817a and 817b. Each of the second pair of inverter circuits 819a and 819b has a second amplification gain (denoted by gₘ₂ₐ). The second pair of cross-coupled inverter circuits 819 can be the same or similar to cross-coupled inverter circuits 709 described above, and therefore is not repeatedly described. For example, cross-coupled inverter circuits 819 can boost the amplification of the second inverter-based stage 810b at high frequencies. In some examples, cross-coupled inverter circuits 819 is optional.

It is understood that each node of the input receiver 800 may have parasitic components associated with it. For example, FIG. 8A shows that each of the differential outputs of the first inverter-based stage 810a may have parasitic capacitance C₁ with respect to electrical ground; and each of the differential outputs of the second inverter-based stage 810b may have parasitic capacitance C₂ with respect to electrical ground. In some cases, C₁ may or may not be equal to C₂. Not all the parasitic components are shown in FIG. 8A.

Cascading of multiple inverter-based stages (e.g., stages 810a and 810b) improves the linearity of the overall gain profile of the input receiver 800, such that the amplification of the input receiver 800 has a flatter shape. This means that the gain variation is reduced across the voltage variation range of the differential mode input voltage of the input receiver 800. FIG. 8B illustrates three waveforms 812, 814, and 815 showing the variations of gains A₁, A₂, and A₃ respectively, when the differential mode input voltage V_{0d} varies across a voltage range. Similar to those above, gain A₁ is measured at the output of the analog frontend 410 with respect to the differential mode input voltage V_{0d}; gain A₂ is measured at the output of the first inverter-based stage 810a with respect to the differential mode input voltage V_{0d}; and gain A₃ is measure at the output of the second inverter-based stage 810b with respect to the differential mode input voltage V_{0d}. For measuring gain A₁, the input signal V_{0d} can be swept from low to high (e.g., from 0V to the power supply voltage), and the gain A₁ can be measured. The amplification gain A₁ is the ratio of the frontend differential output signals Via to the frontend differential input signals, i.e., A₁=V_{1d}/V_{0d}. In the input receiver 800 shown in FIG. 8A, A₁ is calculated based on the below equation [7].

$${A}_{1} = \frac{{V}_{1 d}}{{V}_{o d}} = - \frac{{g}_{m 0} ( 1 - {g}_{m 1 a} {R}_{1} - ( {g}_{m 2} + k {g}_{m 2 a} ) {R}_{1} )}{{g}_{m 1} - {g}_{m 1 a} + {g}_{m 2} - k {g}_{m 2 a}} \qquad [ 7 ]$$

In the above equation [7], gₘ₀ is the gain of the analog frontend 410, gₘ₁ is the gain of the first inverter-based stage 810a, gₘ₂ is the gain of the second inverter-based stage 810b, gₘ₁ₐ is the gain of the first cross-coupled inverters 809, gₘ₂a is the gain of the second cross-coupled inverter circuits 819, and R₁ is the value of the feedback resistor 806 in first inverter-based stage 810a. In equation [7], k is calculated as below in equation [8].

$$k = \frac{1 - {g}_{m 2} {R}_{2}}{1 - {g}_{m 2 a} {R}_{2}} \qquad [ 8 ]$$

In equation [8], R₂ is the value of the feedback resistor 816 in second inverter-based stage 810b. The amplification gain A₂ is the ratio of the first inverter-based stage 810a's differential mode output voltage V_{2d} to the differential mode input voltage V_{0d} (i.e., A₂=V_{2d}/V_{0d}), when stage 810a has a cross-coupled inverter pair 809. Similarly, the amplification gain A₃ is the ratio of the second inverter-based stage 810b's differential mode output voltage V_{3d} to the differential mode input voltage V_{0d} (i.e., A₃=V_{3d}/V_{0d}), when stage 810b has a cross-coupled inverter circuit 819. The gain A₃ thus represents the overall gain of input receiver 800.

With reference to FIG. 8B, waveform 812 shows a relation between gain A₁ and the differential mode input voltage V_{0d}. Waveform 814 shows a relation between gain A₂ and the differential mode input voltage V_{0d}. Waveform 815 shows a relation between gain A₃ and the differential mode input voltage V_{0d}. Comparing the waveforms 812, 814, and 815, by cascading multiple inverter-based stages (e.g., stages 810a and 810b) and optionally including the cross-coupled inverter circuits 809 and 819 at each stage, the range of variation of gain A₃ is reduced at least in a certain voltage range of the differential mode input voltage V_{0d}. As shown in FIG. 8B, waveform 815 is flatter over a substantial range of the differential mode input voltage V_{0d}, which means the gain of input receiver 800 is more linear or equalized over the input voltage range. As described above, a smoother and flatter gain profile across the voltage range of the differential mode input voltage V_{0d} is typically desirable, because it improves the eye opening of the high speed output differential signals, and reduces the inter-symbol interference (ISI).

In the above equation [8], k is negative if

$$\frac{1}{{g}_{m 2}} < {R}_{2} < \frac{1}{{g}_{m 2 a}}$$

and positive for all other cases. The gain A₁ varies from +ve to −ve values (positive and negative values) when the differential mode input voltage (V_{0d}) is varied as shown above. It is understood that the values of R₁, R₂, gₘ₀, gₘ₁, gₘ₂, gₘ₁ₐ, and gₘ₂ₐ can be selected to achieve a linear overall gain of the input receiver 800 which improves ISI. While the above example input receiver 800 shown in FIG. 8A includes only two cascaded inverter-based stages, it is understood that more stages can be cascaded if necessary, depending on the overall requirements for the input receiver (e.g., gain requirements, linearity requirements, ISI requirements, etc.). The number of inverter-based stages can be optimized with considerations of the performance requirements, power consumption, and layout area restrictions.

With reference back to FIG. 8A, the feedback resistors 816 (denoted by R₂) can further improve the bandwidth of the input receiver 800. Without the feedback resistors 816, the zero frequency (denoted by W_{z1}) and the pole frequency (denoted by Wₚ₁) of such a system are calculated as the equations [9] and below.

$${W}_{z 1} \approx \frac{1}{{R}_{1} {C}_{1}} \qquad [ 9 ]$$

$${W}_{p 1} \approx \frac{{g}_{m 1}}{{c}_{1}} \qquad [ 10 ]$$

In the above equations [9] and [10], W_{z1} is the zero frequency, R₁ is the feedback resistor 806 of the first inverter-based stage 810a, gₘ₁ is the gain of the first inverter-based stage 810a, and C₁ is the capacitance at the output of the first inverter-based stage 810a with respect to ground. With the feedback resistor 816 (denoted by R₂) in the second inverter-based stage 810b, the zero and pole frequencies are both extended as shown below in equations [11] and [12], where R₂ is the value of feedback resistor 816 of second inverter-based stage 810b, C₂ is the capacitance at the output the second inverter-based stage 810b. In some example, C₁ and C₂ are intended capacitors included in the input receiver 800. As shown in FIG. 8A, each capacitor C₁ is coupled between a respective differential output of the first inverter-based stage 810a and ground. And each capacitor C₂ is coupled between a respective differential output of the second inverter-based stage 810b and ground. In other cases, they may just be parasitic capacitors or a mix of parasitic capacitors and intended capacitors.

$${W}_{z 1} \approx \frac{1}{{R}_{1} {C}_{1}} + \frac{1}{{R}_{2} {C}_{1}} + \frac{1}{{R}_{2} {C}_{2}} \qquad [ 11 ]$$

$${W}_{p 1} \approx \frac{{g}_{m 1}}{{C}_{1}} + \frac{1}{{R}_{2} {C}_{1}} + \frac{1}{{R}_{2} {C}_{2}} \qquad [ 12 ]$$

A pole frequency is the frequency at which the transfer function of the input receiver approaches infinity. And a zero frequency is the frequency at which the transfer function of an input receiver approaches zero. Thus, by extending one or both of the pole frequency and the zero frequency, the bandwidth of the input receiver 800 is improved, such that the input receiver can operate at a wider range of speed.

An additional benefit of the input receiver 800 having cascaded inverter-based stages is that its analog frontend 410 does not require common mode feedback (CMFB). CMFB is used to regulate the common-mode voltage of a differential amplifier, a differential transistor pair, or other circuitry. The analog frontend 410 as described herein has a high output impedance (i.e., the impedance when looking into the output of the analog frontend 410), and therefore, CMFB may not be needed for such an analog frontend. Furthermore, due to the resistor feedback (e.g., R₁ in the first inverter-based stage 810a and/or R₂ in the second inverter-based stage 810b) the output of the analog frontend 410 (e.g., the common mode of the frontend differential output signals 803a and 803b) can be biased at the trip point of the first inverter-based stage 810a. The trip point of an inverter-based stage is the voltage level at which the stage output switches from one polarity to another polarity (e.g., from low to high, high to low, positive to negative, or negative to positive).

FIG. 8C are illustrative frontend output signal waveforms 832 and 842 for an input receiver with and without cascode circuits in the analog frontend, in accordance with examples as disclosed herein. Waveform 832 corresponds to, for example, output signals from an analog frontend that does not use cascode circuits; and waveform 842 corresponds to, for example, output signals from an analog frontend that uses cascode circuits (e.g., folded cascode circuit in analog frontend 410). As shown in FIG. 8C, for an input receiver that does not use cascode circuit in the analog frontend, the movement of the frontend output differential signals' common mode voltage and the movement of the trip point voltage of the subsequent inverter-based stage may be different. For example, waveform 832 shows that the movement of the common mode voltage is smaller than the movement of the trip point. As a result, the duty cycle of the frontend output differential signals may be less than or greater than 50%. This causes undesired duty cycle distortion.

When the analog frontend uses cascode circuits (e.g., folded cascode circuit in analog frontend 410), the duty cycle distortion is reduced. As shown in waveform 842 of FIG. 8C, when a cascode circuit is used, the movement of the frontend output differential signals' common mode voltage and the movement of the trip point voltage of the subsequent inverter-based stage are substantially equal. Therefore, the duty cycle of the frontend output differential signals (e.g., signals 803a and 803b in FIG. 8A) remains approximately 50%. Thus, by using the cascode circuit described herein, the signal duty cycle of the input receiver can be improved.

It should be noted that the described techniques include possible implementations, and that the operations and the blocks may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor (e.g., processor 310 of FIG. 3), the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An input receiver of an input/output (I/O) circuit operable to communicate data, the input receiver comprising:
an analog frontend configured to receive analog differential input signals from external of the I/O circuit, wherein the analog frontend comprises:
a cascode circuit having differential inputs configured to receive the analog differential input signals and provide frontend differential output signals based on the received analog differential input signals, the cascode circuit being operable in a multi-giga Hertz frequency range;
a biasing circuit configured to control biasing voltages of the cascode circuit; and
cascaded inverter-based stages electrically coupled to the analog frontend to receive the frontend differential output signals and output equalized differential signals representing the data.

2. The input receiver of claim 1, wherein the cascode circuit comprises:
an input transistor pair configured to receive the analog differential input signals;
cascode transistors coupled to the input transistor pair, the cascode transistors are configured to reduce input capacitance of the input transistor pair caused by the Miller capacitance effect; and
current source transistors coupled to the input transistor pair, the current source transistors being controlled by the biasing circuit to provide a current to the cascode transistors.

3. The input receiver of claim 2, wherein the cascode circuit is a folded cascode circuit.

4. The input receiver of claim 3, wherein the biasing circuit is configured such that a common mode of the folded cascode circuit is biased based on termination with respect to ground.

5. The input receiver of claim 1, wherein the biasing circuit comprises:
an operational amplifier configured to receive a reference bias voltage;
one or more current generators configured to generate one or more biasing currents; and
one or more current mirrors configured to mirror the one or more biasing currents and provide biasing voltages to the cascode circuit.

6. The input receiver of claim 1, wherein the cascaded inverter-based stages comprises a first inverter-based stage and a second inverter-based stage, wherein at least one of the first inverter-based stage or the second inverter-based stage comprises one or more resistive feedbacks.

7. The input receiver of claim 6, wherein:
the first inverter-based stage comprises a first pair of inverter circuits coupled to the analog frontend to receive the frontend differential output signals and output first amplified differential signals, each of the first pair of inverter circuits having a first amplification gain; and
the second inverter-based stage comprises a second pair of inverter circuits coupled to the first pair of inverter circuits to receive first amplified differential signals and output second amplified differential signals, each of the second pair of inverters having a second amplification gain.

8. The input receiver of claim 7, wherein the first inverter-based stage comprises a first pair of resistors, each being coupled to an input and an output of a first inverter of the first pair of inverters to form a feedback path associated with the first inverter-based stage.

9. The input receiver of claim 7, wherein the second inverter-based stage comprises a second pair of resistors, each being coupled to an input and an output of a second inverter of the second pair of inverters to form a feedback path associated with the second inverter-based stage.

10. The input receiver of claim 6, further comprising:
a first pair of cross-coupled inverters coupled between differential outputs of the first inverter-based stage to boost a gain of the first inverter-based stage; and
a second pair of cross-coupled inverters coupled between differential outputs of the second inverter-based stage to boost a gain of the second inverter-based stage.

11. The input receiver of claim 6, further comprising:
a first pair of capacitors, each being coupled between a respective differential output of the first inverter-based stage and ground; and
a second pair of capacitors, each being coupled between a respective differential output of the second inverter-based stage and ground.

12. An input receiver of an input/output (I/O) circuit operable to communicate data, the input receiver comprising:
an analog frontend configured to receive analog differential input signals from external of the I/O circuit and provide frontend differential output signals based on the received analog differential input signals, the analog frontend being operable in a multi-giga Hertz frequency range;
a biasing circuit configured to control biasing voltages of the analog frontend; and
cascaded inverter-based stages electrically coupled to the analog frontend to receive the frontend differential output signals and output equalized differential signals representing the data, wherein at least two of the cascaded inverter-based stages comprise resistive feedbacks.

13. The input receiver of claim 12, wherein the analog frontend comprises a cascode circuit.

14. The input receiver of claim 13, wherein the cascode circuit comprises:
an input transistor pair configured to receive the analog differential input signals;
cascode transistors coupled to the input transistor pair, the cascode transistors are configured to reduce input capacitance of the input transistor pair caused by the Miller capacitance effect; and
current source transistors coupled to the input transistor pair, the current source transistors being controlled by the biasing circuit to provide a current to the cascode transistors.

15. The input receiver of claim 13, wherein the cascode circuit is a folded cascode circuit.

16. The input receiver of claim 15, wherein the biasing circuit is configured such that a common mode of the folded cascode circuit is biased based on termination with respect to ground.

17. The input receiver of claim 12, wherein the biasing circuit comprises:
an operational amplifier configured to receive a reference bias voltage;
one or more current generators configured to generate one or more biasing currents; and
one or more current mirrors configured to mirror the one or more biasing currents and provide biasing voltages to the analog frontend.

18. The input receiver of claim 12, wherein the cascaded inverter-based stages comprise:
a first inverter-based stage coupled to the analog frontend to receive the frontend differential output signals; and
a second inverter-based stage coupled to the first inverter-based stage.

19. The input receiver of claim 18, wherein:
the first inverter-based stage comprises a first pair of inverters coupled to the analog frontend to receive the frontend differential output signals and output first amplified differential signals, each of the first pair of inverters having a first amplification gain; and
the second inverter-based stage comprises a second pair of inverters coupled to the first pair of inverters to receive first amplified differential signals and output second amplified differential signals, each of the second pair of inverters having a second amplification gain.

20. The input receiver of claim 19, wherein the first inverter-based stage comprises a first pair of resistors, each being coupled to an input and an output of a first inverter of the first pair of inverters to form a feedback path associated with the first inverter-based stage.

21. The input receiver of claim 18, wherein the second inverter-based stage comprises a second pair of resistors, each being coupled to an input and an output of a second inverter of the second pair of inverters to form a feedback path associated with the second inverter-based stage.

22. The input receiver of claim 18, further comprising:
a first pair of cross-coupled inverters coupled to differential outputs of the first inverter-based stage to boost a gain of the first inverter-based stage; and
a second pair of cross-coupled inverters coupled to differential outputs of the second inverter-based stage to boost a gain of the second inverter-based stage.

23. The input receiver of claim 18, further comprising:
a first pair of capacitors, each being coupled between a respective differential output of the first inverter-based stage and ground; and
a second pair of capacitors, each being coupled between a respective differential output of the second inverter-based stage and ground.

24. A memory device comprising:
an input/output (I/O) circuit having an input receiver comprising:
an analog frontend configured to receive analog differential input signals from external of the I/O circuit, wherein the analog frontend comprises:
a cascode circuit having differential inputs configured to receive the analog differential input signals and provide frontend differential output signals based on the received analog differential input signals, the cascode circuit being operable in a multi-giga Hertz frequency range;
a biasing circuit configured to control biasing voltages of the cascode circuit; and
cascaded inverter-based stages electrically coupled to the analog frontend to receive the frontend differential output signals and output equalized differential signals representing the data;
a memory array coupled to the I/O circuit to receive and transmit data; and
a memory controller configured to control the memory array and the I/O circuit.

25. A system comprising:
a processor;
a first memory controller; and
a memory device coupled to at least one of the processor and the first memory controller, wherein the memory device comprises:
an input/output (I/O) circuit having an input receiver comprising:
an analog frontend configured to receive analog differential input signals from external of the I/O circuit, wherein the analog frontend comprises:
a cascode circuit having differential inputs configured to receive the analog differential input signals and provide frontend differential output signals based on the received analog differential input signals, the cascode circuit being operable in a multi-giga Hertz frequency range;
a biasing circuit configured to control biasing voltages of the cascode circuit; and
cascaded inverter-based stages electrically coupled to the analog frontend to receive the frontend differential output signals and output equalized differential signals representing the data;
a memory array coupled to the I/O circuit to receive and transmit data; and
a second memory controller configured to control the memory array and the I/O circuit.
